(19) United States
(12) Patent Application Publication
(10) Pub. No.: US 2026/0365879 A1
(43) Pub. Date: Nov. 19, 2026

(54) KIT AND METHOD FOR MANUFACTURING SEMICONDUCTOR DEVICE

(71) Applicants: FUJIFILM Corporation, Tokyo (JP); FUJIFILM Electronic Materials U.S.A., Inc., North Kingstown, RI (US)

(72) Inventors: Tetsuya KAMIMURA, Shizuoka (JP); Atsushi MIZUTANI, Shizuoka (JP); Bin HU, Mesa, AZ (US); Yannan LIANG, Mesa, AZ (US); Nobuaki SUGIMURA, Mesa, AZ (US); Ting-Kai HUANG, Mesa, AZ (US); Hanyu FAN, Mesa, AZ (US); Wei LI, Mesa, AZ (US); Hyosang LEE, Mesa, AZ (US)

(73) Assignees: FUJIFILM Corporation, Tokyo (JP); FUJIFILM Electronic Materials U.S.A., Inc., North Kingstown, RI (US)

(21) Appl. No.: 19/710,363

(22) Filed: Jun. 16, 2026

Related U.S. Application Data
(63) Continuation of application No. PCT/JP2024/043719, filed on Dec. 11, 2024.
(60) Provisional application No. 63/613,764, filed on Dec. 22, 2023.

(51) Int. Cl. C09G 1/02; C11D 7/32; H10P 52/40; H10P 70/00

(52) U.S. Cl. CPC C09G 1/02; C11D 7/3209; C11D 7/3218; C11D 7/3281; H10P 52/403; H10P 70/277

(57) ABSTRACT

Provided are a kit including a polishing liquid and a washing liquid and a method for manufacturing a semiconductor device using the kit. The kit, when used for a treatment in which a treatment target is subjected to chemical mechanical polishing and the treatment target subjected to chemical mechanical polishing is further washed, can suppress the occurrence of scratches on the treatment target surface and leaves less organic residues on the treatment target surface.

The kit for use in subjecting a treatment target to chemical mechanical polishing and further washing the treatment target subjected to chemical mechanical polishing includes a polishing liquid and a washing liquid. The polishing liquid includes an abrasive grain, a nonionic surfactant, and a specific azole compound selected from the group consisting of benzotriazole and derivatives thereof and has a pH of 7.0 or more, and the washing liquid includes an amine compound.

### CROSS-REFERENCE TO RELATED APPLICATIONS

This application is a Continuation of PCT International Application No. PCT/JP2024/043719 filed on Dec. 11, 2024, which claims priority under 35 U.S.C. § 119 (e) to U.S. Patent Application No. 63/613,764 filed on Dec. 22, 2023. The above applications are hereby expressly incorporated by reference, in their entirety, into the present application.

### BACKGROUND OF THE INVENTION

### 1. Field of the Invention

The present invention relates to a kit and a method for manufacturing a semiconductor device.

### 2. Description of the Related Art

In the development of semiconductor devices typified by semiconductor integrated circuits (LSI: large-scale integrated circuits), in order to achieve smaller sizes and higher speeds, higher density and higher integration provided by miniaturization and lamination of wiring lines have been required. In response to such demands, in the manufacture of a semiconductor device, chemical mechanical polishing (CMP) is used for flattening of a bare wafer, flattening of an interlayer insulating film, formation of a metal plug, formation of an embedded wiring line, etc. In CMP, residues of, for example, an abrasive grain used in CMP and a metal component derived from, for example, a wiring metal film and/or barrier metal that has been subjected to polishing may remain on a semiconductor substrate surface after polishing. Thus, a process of removing these residues by using a washing liquid is generally performed after CMP.

In such a manufacturing process of a semiconductor device, there are various requirements for the characteristics and compositions of members used in the above steps according to the components and intended use of a treatment target.

For example, U.S. Patent Application Publication No. 2021/284868 discloses a polishing liquid including an abrasive and a specific polyoxyalkylene ether compound and a method of chemical mechanical polishing treatment using the polishing liquid.

### SUMMARY OF THE INVENTION

When a treatment target is subjected to chemical mechanical polishing and the treatment target subjected to chemical mechanical polishing is further washed, it is required that there be few scratches and few organic residues on the surface of the final treatment target.

The present inventors have studied the chemical mechanical polishing treatment using the polishing liquid specifically disclosed in the above document, and found that scratch suppressibility and organic residue removability cannot be achieved at the same time depending on the combination with a washing liquid used after the treatment, and there is room for further study.

Thus, it is an object of the present invention to provide a kit including a polishing liquid and a washing liquid, the kit, when used for a treatment in which a treatment target is subjected to chemical mechanical polishing and the treatment target subjected to chemical mechanical polishing is further washed, being able to suppress the occurrence of scratches on the treatment target surface and leaving less organic residues on the treatment target surface.

It is also an object of the present invention to provide a method for manufacturing a semiconductor device using the kit.

As a result of intensive studies to achieve the above objects, the present inventors have found that the objects can be achieved by the following configurations.

[1] A kit for use in subjecting a treatment target to chemical mechanical polishing and further washing the treatment target subjected to chemical mechanical polishing, the kit including:
a polishing liquid; and
a washing liquid,
wherein the polishing liquid includes an abrasive grain, a nonionic surfactant, and a specific azole compound selected from the group consisting of benzotriazole and derivatives thereof and has a pH of 7.0 or more, and
the washing liquid includes an amine compound.

[2] The kit according to [1], wherein the pH of the polishing liquid is 8.8 to 11.5.

[3] The kit according to [1] or [2], wherein the abrasive grain is a colloidal silica having an average particle diameter of 5 to 100 nm.

[4] The kit according to any one of [1] to [3], wherein a mass ratio of a content of the nonionic surfactant to a content of the specific azole compound is 0.01 to 100.00.

[5] The kit according to any one of [1] to [4], wherein at least one of the polishing liquid or the washing liquid further includes an organic acid.

[6] The kit according to [5], wherein the organic acid includes at least one organic acid selected from the group consisting of polycarboxylic acids and polyphosphonic acids.

[7] The kit according to any one of [1] to [6], wherein the polishing liquid further includes an alcohol.

[8] The kit according to [7], wherein a content of the alcohol is 0.1 to 1000 mass ppm relative to a total mass of the polishing liquid.

[9] The kit according to [7], wherein the alcohol is selected from the group consisting of methanol, ethanol, 1-propanol, and isopropanol.

[10] The kit according to any one of [1] to [9],
wherein the specific azole compound included in the polishing liquid comprises at least two specific azole compounds.

[11] The kit according to [10], wherein at least one of the specific azole compounds is a compound represented by formula (I) described later or a compound represented by formula (II) described later.

[12] The kit according to any one of [1] to [11], wherein the nonionic surfactant is an alcohol alkoxylate.

[13] The kit according to any one of [1] to [12], wherein the washing liquid has a pH of 9.0 to 14.0.

[14] The kit according to any one of [1] to [13], wherein the washing liquid further includes an anticorrosive.

[15] The kit according to [14], wherein the anticorrosive includes at least one compound selected from the group consisting of purine and purine derivatives.

[16] The kit according to any one of [1] to [15], wherein a content of the amine compound is 0.06 to 8.0 mass % relative to a total mass of the washing liquid.

[17] The kit according to any one of [1] to [16], wherein a ratio of a content of the nonionic surfactant relative to a total mass of the polishing liquid to a content of the amine compound relative to a total mass of the washing liquid is 0.05 to 8.00.

[18] The kit according to any one of [1] to [17], wherein a ratio of a content of the specific azole compound relative to a total mass of the polishing liquid to a content of the amine compound relative to a total mass of the washing liquid is 0.005 to 0.90.

[19] The kit according to any one of [1] to [18], wherein the amine compound is at least one amine compound selected from the group consisting of secondary amine compounds, tertiary amine compounds, and quaternary ammonium compounds.

[20] The kit according to any one of [1] to [19],
wherein the amine compound includes at least one selected from the group consisting of a compound represented by formula (A1) described later and a compound represented by formula (A2) described later.

[21] The kit according to any one of [1] to [20], wherein the treatment target includes copper.

[22] A method for manufacturing a semiconductor device using the kit according to any one of [1] to [21], the method including: a step 1 of subjecting a treatment target to chemical mechanical polishing using the polishing liquid; and
a step 2, after the step 1, of washing the treatment target subjected to chemical mechanical polishing using the washing liquid.

[23] The method according to claim [22], further comprising:
a step 1a, after step 1 and prior to step 2, of pad washing the treatment target subjected to chemical mechanical polishing using the washing liquid as a composition for pad washing.

The present invention can provide a kit including a polishing liquid and a washing liquid, the kit, when used for a treatment in which a treatment target is subjected to chemical mechanical polishing and the treatment target subjected to chemical mechanical polishing is further washed, being able to suppress the occurrence of scratches on the treatment target surface and leaving less organic residues on the treatment target surface.

The present invention can also provide a method for manufacturing a semiconductor device using the kit.

### DESCRIPTION OF THE PREFERRED EMBODIMENTS

Hereinafter, the present invention will be described in detail.

It should be appreciated that although the following description of constituent features may be made in the context of a representative embodiment of the present invention, the present invention is not limited to the embodiment.

In the present specification, any numerical range expressed using “to” means a range including numerical values before and after “to” as lower and upper limit values.

In the present specification, when a component is constituted by two or more components, the “content” of the component means the total content of the two or more components.

In numerical ranges described in stages in the present specification, the upper limit value or the lower limit value described in one numerical range may be replaced with the upper limit value or the lower limit value of other numerical ranges described in stages. In numerical ranges described in the present specification, the upper limit value or the lower limit value described in one numerical range may be replaced with values described in Examples.

In the present specification, the “total solid contents in the polishing liquid” means the total mass of all components included in the polishing liquid excluding water and solvents such as organic solvents, and the “total solid contents in the washing liquid” means the total mass of all components included in the washing liquid excluding water and solvents such as organic solvents.

A compound described in the present specification may include a structural isomer, an optical isomer, and an isotope unless otherwise specified. The structural isomer, the optical isomer, and the isotope included may be of one type or two or more types.

In the present specification, when a plurality of substituents, linking groups, or the like (hereinafter referred to as “substituents or the like”) are represented by a particular symbol or when a plurality of substituents or the like are simultaneously defined, it is meant that the substituents or the like may be the same or different from each other. This also applies to the definition of the number of substituents or the like.

The bonding direction of a divalent group given in the present specification is not limited unless otherwise specified. For example, in a compound represented by a formula “X-Y-Z” where Y is —COO—, Y may be —CO—O— or —O—CO—. This compound may be represented as “X—CO—O—Z” or “X—O—CO—Z”.

In the present specification, “ppm” means “parts-per-million (10-6)”, “ppb” means “parts-per-billion (10-9)”, and “ppt” means “arts-per-trillion (10-12)”.

In the present specification, a “weight-average molecular weight (Mw)” and a “polydispersity index (PDI)” mean values determined by gel permeation chromatography (GPC) in terms of polyethylene glycol unless otherwise specified.

In the present specification, “1 angstrom” corresponds to “0.1 nm”.

### {Kit}

Hereinafter, a kit according to the present invention will be described in detail.

The kit according to the present invention is a kit for use in subjecting a treatment target to chemical mechanical polishing and further washing the treatment target subjected to chemical mechanical polishing. The kit includes a polishing liquid and a washing liquid. The polishing liquid includes an abrasive grain, a nonionic surfactant, and a specific azole compound selected from the group consisting of benzotriazole and derivatives thereof and has a pH of 7.0 or more, and the washing liquid includes an amine compound.

Although the reason why the kit having the above configuration can achieve the objects of the present invention is not necessarily clear, the present inventors presume as follows.

It should be noted that the following presumption does not limit the mechanism by which the effect is produced. In other words, cases where the effect is produced by mechanisms other than the following are also within the scope of the present invention.

If aggregates of polishing debris resulting from polishing and/or abrasive grains are formed during CMP, the aggregates may scrape the surface of a treatment target to cause scratches. The polishing liquid of the kit includes a nonionic surfactant and a specific azole compound as well as an abrasive grain and has a pH of 7.0 or more. Presumably, this configuration can inhibit aggregation of polishing debris and/or abrasive grains to suppress the occurrence of scratches. Furthermore, due to the configuration of the polishing liquid and the presence of an amine compound in the washing liquid, the components effectively react with each other, whereby residues (organic residues) derived from the polishing liquid can be efficiently removed by the washing liquid.

Hereinafter, regarding the case where the kit according to the present invention is used for a treatment in which a treatment target is subjected to chemical mechanical polishing and the treatment target subjected to chemical mechanical polishing is further washed, the ability to suppress the occurrence of scratches on the resulting treatment target surface is also referred to simply as “scratch suppressibility”, the ability to leave less organic residues is also referred to simply as “organic residue removability”, and the case where at least one of the scratch suppressibility or the organic residue removability is higher is also referred to as “the effect of the present invention is better produced”.

Hereinafter, the polishing liquid and the washing liquid constituting the kit according to the present invention will be described in detail.

### <<Polishing Liquid>>

The polishing liquid includes an abrasive grain, a nonionic surfactant, and a specific azole compound selected from the group consisting of benzotriazole and derivatives thereof and has a pH of 7.0 or more.

Hereinafter, components that can be included in the polishing liquid and the properties thereof will be described in detail.

### <Abrasive Grain>

The polishing liquid includes an abrasive grain.

The abrasive grain is not particularly limited as long as it is an abrasive grain used for chemical mechanical polishing in a semiconductor manufacturing process, and a known abrasive grain can be used.

As the abrasive grain, for example, inorganic abrasive grains such as silica, alumina, zirconia, ceria, titania, germania, and silicon carbide; and organic abrasive grains such as polystyrene, polyacrylic, and polyvinyl chloride can be used. In particular, silica particles are preferred for high dispersion stability in the polishing liquid and high scratch suppressibility.

Examples of the silica particles include, but are not limited to, precipitated silica, fumed silica, and colloidal silica, and colloidal silica is preferred. Colloidal silica refers to silica (silicon oxide) particles dispersed on a colloid in a dispersion medium.

For higher scratch suppressibility, the average particle diameter of the abrasive grain is preferably 300 nm or less, more preferably 100 nm or less, still more preferably 80 nm or less. For higher dispersion stability of the abrasive grain, the lower limit is preferably 1 nm or more, more preferably 3 nm or more, still more preferably 5 nm or more. The average particle diameter is a value determined using dynamic light scattering, and can be measured with, for example, a nanoparticle analyzer nanoPartica SZ-100V2 (manufactured by Otsuka Electronics Co., Ltd.).

For further improved polishing efficiency, the average aspect ratio of the abrasive grain is preferably 1.5 to 2.0, more preferably 1.55 to 1.95, still more preferably 1.6 to 1.9.

The average aspect ratio of the abrasive grain is determined by measuring the major axis and the minor axis of each of 100 particles randomly selected under a transmission electron microscope, calculating the aspect ratio (major axis/minor axis) of each particle, and arithmetically averaging the aspect ratios of the 100 particles. The major axis of a particle means a length of the particle in the major axis direction, and the minor axis of a particle means a length of the particle in a direction perpendicular to the major axis direction of the particle.

For a further improved polishing rate, the degree of aggregation of the abrasive grain is preferably 1 to 3.

The degree of aggregation is a value determined by the degree of aggregation=average secondary particle diameter/average primary particle diameter. The average secondary particle diameter and the average primary particle diameter can be measured using a known method. A catalog value may be employed as the degree of aggregation.

The colloidal silica may have, on its surface, a surface-modifying group (e.g., a sulfo group, a phosphonic acid group, a carboxylic acid group, or an amino group). These groups may be ionized in the polishing liquid.

Examples of the method of obtaining the colloidal silica having a surface-modifying group include, but are not limited to, a method described in JP2010-269985A.

The abrasive grain may be a commercially available product, and examples of commercially available colloidal silicas include PL-1, PL-3, PL-7, PL-10, PL-5D, PL-3D, PL-2D, PL-1D, PL-07D, PL-5C, PL-3C, and PL-1C (all product names, manufactured by Fuso Chemical Co., Ltd.).

The content of the abrasive grain is preferably 0.01 to 10.0 mass %, more preferably 0.1 to 7.0 mass %, still more preferably 1.0 to 5.0 mass %, relative to the total mass of the polishing liquid. From the viewpoint of polishing efficiency and temporal stability, the content of the abrasive grain is preferably 5.0 to 80.0 mass %, more preferably 20.0 to 70.0 mass %, still more preferably 40.0 to 60.0 mass %, relative to the total solid contents in the polishing liquid.

One abrasive grain may be used alone, or two or more abrasive grains may be used. When two or more abrasive grains are used, their total content is preferably within the above ranges.

### <Nonionic Surfactant>

The polishing liquid includes a nonionic surfactant.

Examples of the nonionic surfactant include polyalkylene oxide alkylphenyl ether-based surfactants, alcohol alkoxylate (polyalkylene oxide alkyl ether)-based surfactants, block polymer-based surfactants composed of polyethylene oxide and polypropylene oxide, polyoxyalkylene di-styrenated phenyl ether-based surfactants, polyalkylene tribenzylphenyl ether-based surfactants, acetylene polyalkylene oxide-based surfactants, polyoxyethylene sorbitol fatty acid ester-based surfactants, and polyoxyethylene alkylamine-based surfactants. In particular, the nonionic surfactant is preferably an alcohol alkoxylate.

The alcohol alkoxylate is preferably a compound represented by formula (b) below.

R-L¹-(L²O)ₙ—H Formula (b)

In formula (b) above, R represents an alkyl group.

L¹ represents a single bond, an oxygen atom, or an alkylene group optionally having an oxygen atom.

L² represents an alkylene group having 2 or 3 carbon atoms, and a plurality of L²'s may be the same or different.

n represents a number of 2 or greater.

In formula (b) above, the number of carbon atoms of the alkyl group represented by R is preferably 5 to 25, more preferably 8 to 20, still more preferably 10 to 18. The alkyl group may be linear or branched.

The number of carbon atoms of the alkylene group optionally having an oxygen atom represented by L¹ is preferably 1 to 20, more preferably 1 to 10, still more preferably 1 to 5.

n is preferably 3 to 50, more preferably 4 to 30, still more preferably 6 to 20.

Examples of the alkylene group optionally having an oxygen atom include —O—CH₂—CH₂— and —O—CH₂—CH₂—CH₂—.

The nonionic surfactant may be a commercially available product. Examples of the commercially available product include Surfynol 61, 82, 440, 465, 485, MD20, Dynol 604, and 607 manufactured by Air Products & Chemicals, Inc., Olfine STG and Olfine E1010 manufactured by Nissin Chemical Co., Ltd., EMULGEN 103, 106, 108, 150, 220, 404, 102 KG, AMIET 320, RHEODOL TW-S320V, 430, 430V, and 460 manufactured by Kao Chemicals, and LF-EP-61 and LF-EP-40 manufactured by Verdant Specialty Solutions.

For the effect of the present invention to be better produced, the hydrophile-lipophile balance (HLB) value of the nonionic surfactant is preferably 3 to 20, more preferably 8 to 17, still more preferably 8 to 15. The HLB value is defined as a value calculated from the Griffin formula (20×Mw/M; Mw=molecular weight of hydrophilic site, M=molecular weight of nonionic surfactant), and in some cases, a catalog value or a value calculated by another method may be used. HLB values closer to 20 mean being more hydrophilic, and HLB values closer to 0 mean being more lipophilic.

For the effect of the present invention to be better produced, the content of the nonionic surfactant is preferably 0.001 to 5.0 mass %, more preferably 0.005 to 1.5 mass %, still more preferably 0.01 to 1.2 mass %, relative to the total mass of the polishing liquid.

The content of the nonionic surfactant is preferably 0.01 to 40.0 mass %, more preferably 0.1 to 25.0 mass %, still more preferably 0.2 to 23.0 mass %, relative to the total solid contents in the polishing liquid.

One nonionic surfactant may be used alone, or two or more nonionic surfactants may be used. When two or more nonionic surfactants are used, their total content is preferably within the above ranges.

### <Specific Azole Compound>

The polishing liquid includes a specific azole compound selected from the group consisting of benzotriazole (BTA) and derivatives thereof.

BTA derivatives are not particularly limited as long as they are compounds derived by substituting a hydrogen atom of BTA with a substituent, but 5-methylbenzotriazole (MBTA), 5-chlorobenzotriazole (CBTA), 5-butylbenzotriazole (BBTA), a compound represented by formula (I), or a compound represented by formula (II) is preferred.

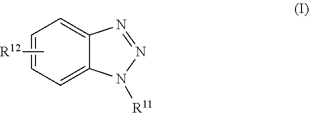

In formula (I), R¹¹ and R¹² each independently represent a hydrogen atom, a hydroxy group, a carboxy group, or an optionally substituted hydrocarbon group, provided that the compound represented by formula (I) does not include any of BTA, MBTA, CBTA, and BBTA.

The hydrocarbon group represented by R¹¹ and R¹² is, for example, an alkyl group, an alkenyl group, an alkynyl group, an aryl group, an aralkyl group, or a combination thereof, preferably an alkyl group or an aryl group.

The number of carbon atoms of the alkyl group is preferably 1 to 12, more preferably 1 to 6, still more preferably 1 to 3. The number of carbon atoms of the alkenyl group and the alkynyl group is preferably 2 to 12, more preferably 2 to 6.

The number of carbon atoms of the aryl group is preferably 5 to 18, more preferably 6 to 14, still more preferably 6 to 10. The number of carbon atoms of the aralkyl group is preferably 6 to 23, more preferably 7 to 15, still more preferably 7 to 11.

The substituent that the hydrocarbon group may have is, for example, an alkyl group, an aryl group, an aralkyl group, a heteroaryl group, a hydroxy group, a carboxy group, —N(Rₐ)(R_{b}), or a combination thereof. Rₐ and R_{b} each independently represent a hydrogen atom or an organic group.

Preferred forms of the alkyl group, the aryl group, and the aralkyl group serving as the substituents are the same as those of the alkyl group, the aryl group, and the aralkyl group represented by R¹¹ and R¹².

The number of ring members of the heteroaryl group serving as the substituent is preferably 6 to 14, still more preferably 6 to 10. The heteroatom of the heteroaryl group is preferably a nitrogen atom, an oxygen atom, or a sulfur atom.

The organic group represented by Rₐ and R_{b} is preferably an alkyl group or a hydroxyalkyl group. The number of carbon atoms of the alkyl group and the hydroxyalkyl group is, for example, 1 to 12, preferably 1 to 8, more preferably 1 to 4.

R¹¹ is preferably a hydrogen atom, an optionally substituted alkyl group, or an optionally substituted aryl group.

The substituent on the alkyl group represented by R¹¹ is preferably an aryl group or —N(Rₐ)(R_{b}), more preferably —N(Rₐ)(R_{b}). The substituent on the aryl group represented by R¹¹ is preferably a hydroxy group, an alkyl group, or an aralkyl group, more preferably a hydroxy group or an alkyl group.

R¹² is preferably a hydrogen atom, a hydroxy group, a carboxy group, or an optionally substituted alkyl group, more preferably a hydroxy group or an alkyl group.

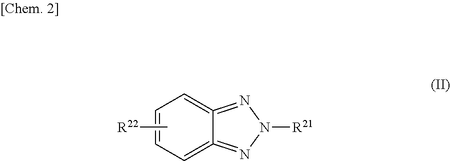

In formula (II), R²¹ and R²² each independently represent a hydrogen atom, a hydroxy group, a carboxy group, or an optionally substituted hydrocarbon group, provided that the compound represented by formula (II) does not include BTA, MBTA, CBTA, and BBTA.

The definition and preferred forms of the group represented by R²¹ are the same as those of the group represented by R¹¹ in the group represented by formula (I), and the definition and preferred forms of the group represented by R²² are the same as those of the group represented by R¹² in the group represented by formula (I).

Examples of the specific azole compound include the following compounds.

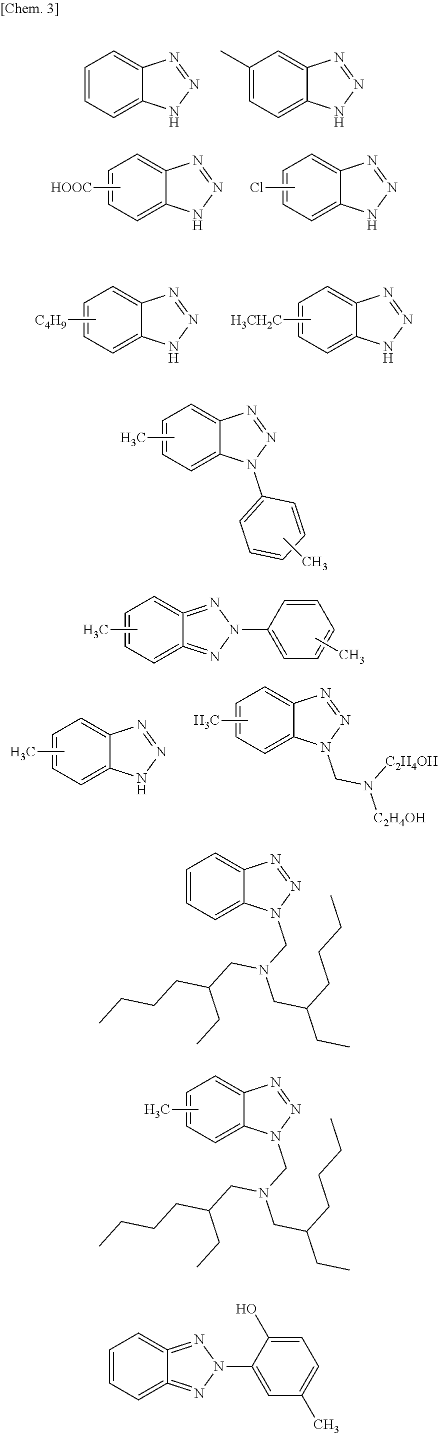

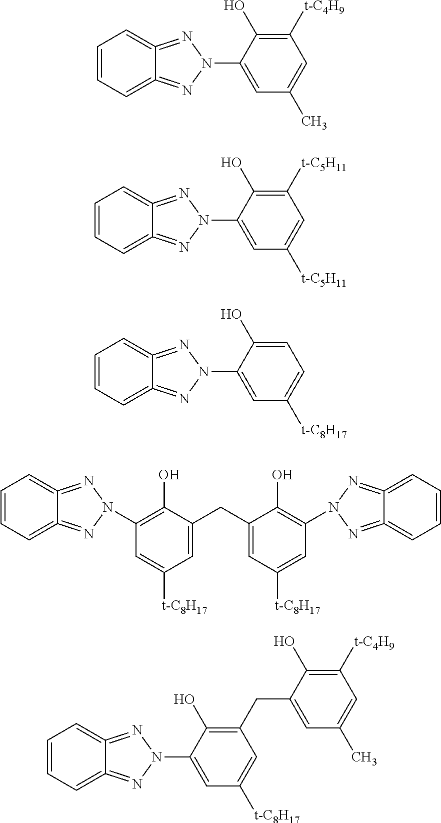

One specific azole compound may be used alone, or two or more specific azole compounds may be used in combination.

The specific azole compound preferably includes at least one selected from the group consisting of BTA, MBTA, BBTA, and CBTA.

For higher interfacial corrosion suppressibility, the polishing liquid preferably includes two or more specific azole compounds, and at least one of them is more preferably a compound represented by formula (I) or a compound represented by formula (II).

In particular, the polishing liquid still more preferably includes at least one selected from the group consisting of BTA, MBTA, BBTA, and CBTA and at least one selected from the group consisting of a compound represented by formula (I) and a compound represented by formula (II).

The interfacial corrosion suppressibility means, in the case where the treatment target has a metal layer and a layer formed of a material different from that of the metal layer (e.g., an insulating layer and a barrier layer), the ability to suppress corrosion at the interface between these layers.

The content of the specific azole compound is preferably 0.0001 to 5.0 mass %, more preferably 0.005 to 3.0 mass %, still more preferably 0.008 to 0.8 mass %, relative to the total mass of the polishing liquid.

The content of the specific azole compound is preferably 0.01 to 40.0 mass %, more preferably 0.015 to 15.0 mass %, still more preferably 0.1 to 5.0 mass %, relative to the total solid contents in the polishing liquid.

The mass ratio of the content of the nonionic surfactant to the content of the specific azole compound is preferably 0.001 to 300.00, more preferably 0.01 to 100.00, still more preferably 0.15 to 80.00.

When two or more specific azole compounds are used, their total content is preferably within the above ranges.

### <Organic Acid>

The polishing liquid may include an organic acid, and preferably includes an organic acid for higher scratch suppressibility.

The organic acid is a compound including at least one carbon atom and an acid group and is different from the specific azole compound described above.

The organic acid may be a compound having a functional group (coordinating group) that can function as a ligand.

The acid group of the organic acid is, for example, a carboxy group, a phosphonic acid group, or a sulfo group, preferably a carboxy group or a phosphonic acid group. The number of acid groups of the organic acid is not limited as long as it is one or more, but is preferably two or more. That is, the organic acid preferably includes at least one organic acid selected from the group consisting of polycarboxylic acids and polyphosphonic acids, more preferably includes a polycarboxylic acid, still more preferably includes a divalent or trivalent carboxylic acid.

The organic acid preferably has a low molecular weight. Specifically, the molecular weight of the organic acid is preferably 600 or less, more preferably 450 or less, still more preferably 300 or less. The lower limit is preferably 50 or more, more preferably 100 or more.

The number of carbon atoms of the organic acid is preferably 1 to 15, more preferably 2 to 15.

The organic acid may be an organic acid having a carboxy group, an organic acid having a phosphonic acid group, or an organic acid having a sulfo group.

Examples of the organic acid having a carboxy group include polycarboxylic acids, aminocarboxylic acids, and hydroxycarboxylic acids.

Examples of the polycarboxylic acids include malonic acid, oxalic acid, succinic acid, glutaric acid, adipic acid, pimelic acid, sebacic acid, maleic acid, and adipic acid, and malonic acid, oxalic acid, and succinic acid are preferred.

Examples of the aminocarboxylic acids include glycine and derivatives thereof, histidine and derivatives thereof, alanine (2-aminopropionic acid or 3-aminopropionic acid), arginine, asparagine, aspartic acid, cystine, cysteine, glutamine, glutamic acid, isoleucine, leucine, lycine, methionine, phenylalanine, serine, ethionine, threonine, tyrosine, valine, tryptophan, 2-amino-3-aminopropanoic acid, and proline, and glycine and derivatives thereof are preferred.

Examples of the aminocarboxylic acids also include compounds described in paragraphs to of JP2016-086094A.

Examples of the glycine derivatives include N,N-di(2-hydroxyethyl)glycine.

Examples of the hydroxycarboxylic acids include citric acid, malic acid, glycolic acid, gluconic acid, heptonic acid, tartaric acid, lactic acid, phenyllactic acid, hydroxyphenyllactic acid, and phenylsuccinic acid, and citric acid, tartaric acid, and lactic acid are preferred.

Examples of the organic acid having a phosphonic acid group include phosphonic acids; specific examples include ethylenediamine tetra(methylenephosphonic acid) (EDTPO), etidronic acid (HEDP), 1-hydroxyethylidene-1,1′-diphosphonic acid (HEDPO), 1-hydroxypropylidene-1,1′-diphosphonic acid, 1-hydroxybutylidene-1,1′-diphosphonic acid, ethylaminobis(methylenephosphonic acid), dodecylaminobis(methylenephosphonic acid), nitrilotris(methylenephosphonic acid) (NTPO), ethylenediamine bis(methylenephosphonic acid) (EDDPO), 1,3-propylenediamine bis(methylenephosphonic acid), ethylenediamine tetra(ethylenephosphonic acid), 1,3-propylenediamine tetra(methylenephosphonic acid) (PDTMP), 1,2-diaminopropane tetra(methylenephosphonic acid), 1,6-hexamethylenediamine tetra(methylenephosphonic acid), diethylenetriamine penta(methylenephosphonic acid) (DEPPO), diethylenetriamine penta (ethylenephosphonic acid), triethylenetetramine hexa(methylenephosphonic acid), and triethylenetetramine hexa (ethylenephosphonic acid). In particular, the organic acid having a phosphonic acid group is preferably EDTPO, HEDP, or HEDPO.

Examples of the organic acid having a phosphonic acid group also include compounds described in paragraphs to of WO2018/020878A and compounds ((co) polymers) described in paragraphs to of WO2018/030006A, the contents of which are incorporated herein.

In particular, the organic acid is preferably malonic acid, citric acid, oxalic acid, tartaric acid, succinic acid, glycine, EDTPO, HEDP, or HEDPO, more preferably malonic acid, citric acid, succinic acid, or EDTPO.

The content of the organic acid is preferably 0.001 to 5.0 mass %, more preferably 0.01 to 3.0 mass %, still more preferably 0.01 to 1.0 mass %, relative to the total mass of the polishing liquid. The content of the organic acid is preferably 0.1 to 20.0 mass %, more preferably 0.5 to 10.0 mass %, relative to the total solid contents in the polishing liquid.

The mass ratio of the content of the specific azole compound to the content of the organic acid is preferably 0.001 or more, more preferably 0.003 or more. The upper limit is preferably 3.00 or less, more preferably 1.00 or less, still more preferably 0.50 or less.

One organic acid may be used alone, or two or more organic acids may be used. When two or more organic acids are used, their total content is preferably within the above ranges.

### <Alcohol>

The polishing liquid may include an alcohol, and preferably includes an alcohol for higher organic residue removability.

The alcohol is a compound different from the nonionic surfactant, the specific azole compound, and the organic acid described above.

The alcohol may be a polyhydric alcohol having a plurality of hydroxy groups, but is preferably a monohydric alcohol.

The molecular weight of the alcohol is not particularly limited, but is preferably 32 to 290, more preferably 32 to 100, still more preferably 32 to 80.

For the effect of the present invention to be better produced, the alcohol is preferably an alkyl alcohol, more preferably an alcohol selected from the group consisting of methanol, ethanol, 1-propanol, and isopropanol.

For higher interfacial corrosion suppressibility, the content of the alcohol is preferably 5000 mass ppm or less, more preferably 2000 mass ppm or less, still more preferably 1000 mass ppm or less, relative to the total mass of the polishing liquid. The lower limit is often 0.01 mass ppm or more, preferably 0.1 mass ppm or more.

One alcohol may be used alone, or two or more alcohols may be used. When two or more alcohols are used, their total content is preferably within the above range.

### <Water>

The polishing liquid may include water.

The water included in the polishing liquid is not particularly limited, and distilled water, deionized (DI) water, pure water (ultrapure water), or the like can be used.

The content of the water may be any amount as long as the water is the balance excluding the components that can be included in the polishing liquid, but is preferably 55.0 to 99.0 mass %, more preferably 75.0 to 97.0 mass %, still more preferably 80.0 to 97.0 mass %, relative to the total mass of the polishing liquid.

### <Oxidizing Agent>

The polishing agent may include an oxidizing agent, and preferably includes an oxidizing agent for further improved polishing efficiency.

The oxidizing agent is not particularly limited, but is preferably a compound capable of oxidizing copper. Examples of the oxidizing agent include hydrogen peroxide, ozone water, rare earth metal oxides, percarbonates, permanganates, cerium compounds, ferricyanides; and periodic acid, persulfuric acid, chloric acid, hypochlorous acid, bromic acid, iodic acid, chromic acid, perboric acid, peracetic acid, perbenzoic acid, potassium dichromate, and salts thereof, and hydrogen peroxide is preferred.

The content of the oxidizing agent is preferably 0.1 to 15.0 mass %, more preferably 0.5 to 10.0 mass %, still more preferably 1.0 to 5.0 mass %, relative to the total mass of the polishing liquid. From the viewpoint of polishing efficiency and storage stability, the content of the oxidizing agent is preferably 5.0 to 80.0 mass %, more preferably 20.0 to 70.0 mass %, still more preferably 40.0 to 60.0 mass %, relative to the total solid contents in the polishing liquid.

One oxidizing agent may be used alone, or two or more oxidizing agents may be used. When two or more oxidizing agents are used, their total content is preferably within the above ranges.

### <Other Components>

The polishing liquid may include other components other than the components described above. Examples of the other components include pH adjusters, surfactants other than nonionic surfactants, water-soluble polymers, and organic solvents other than alcohols.

### —pH Adjuster—

The polishing liquid may include a pH adjuster in order to adjust and maintain the pH of the polishing liquid.

The pH adjuster is a basic compound or an acidic compound different from the above-described compounds that can be included in the polishing liquid. However, it is permissible to adjust the pH of the polishing liquid by adjusting the amounts of the above-described components.

The basic compound is a compound that is alkaline (pH>7.0) in an aqueous solution.

The basic compound may be a basic inorganic compound; examples include alkali metal hydroxides such as sodium hydroxide and potassium hydroxide, alkaline earth metal hydroxides, and ammonia.

The acidic compound is a compound that is acidic (pH<7.0) in an aqueous solution.

The acidic compound may be an inorganic acid; examples include hydrochloric acid, sulfuric acid, sulfurous acid, nitric acid, nitrous acid, phosphoric acid, hexafluorophosphoric acid, and boric acid.

The acidic compound may be a salt of an acidic compound if it becomes an acid or an acid ion (anion) in an aqueous solution.

The content of the pH adjuster can be selected according to the types and amounts of other components and the desired pH of the polishing liquid. For example, the content of the pH adjuster is preferably 0.01 to 10.0 mass %, more preferably 0.1 to 8.0 mass %, relative to the total mass of the polishing liquid.

The content of the pH adjuster is preferably 0.01 to 80.0 mass %, more preferably 0.1 to 60.0 mass %, relative to the total solid contents in the polishing liquid.

One pH adjuster may be used alone, or two or more pH adjusters may be used. When two or more pH adjusters are used, their total content is preferably within the above ranges.

### —Surfactant—

The polishing liquid may include a surfactant other than nonionic surfactants. The surfactant other than nonionic surfactants is not particularly limited as long as it is a compound having a hydrophilic group and a hydrophobic group (lipophilic group) in one molecule and having an ionic moiety; examples include cationic surfactants, amphoteric surfactants, and anionic surfactants.

Examples of the cationic surfactants include alkylpyridium-based surfactants and alkylamine acetic acid-based surfactants.

Examples of the amphoteric surfactants include carboxybetaine-type amphoteric surfactants, sulfobetaine-type amphoteric surfactants, aminocarboxylic acid salts, imidazolinium betaine, lecithin, alkylamine oxides, and mixtures thereof.

Examples of the anionic surfactants include phosphoric acid ester-based surfactants having a phosphoric acid ester group as a hydrophilic group (acid group) and sulfuric acid ester-based surfactants having a sulfuric acid ester group as a hydrophilic group (acid group).

As the surfactant, for example, compounds described in paragraphs to of WO2022/044893A, the contents of which are incorporated herein, can be used.

### —Water-Soluble Polymer—

The polishing liquid may include a water-soluble polymer. Examples of the water-soluble polymer include polyvinyl alcohol, polyvinylpyrrolidone, and polyacrolein.

### —Organic Solvent—

The polishing liquid may include an organic solvent other than alcohols.

The organic solvent may be a known organic solvent; examples include glycol diether solvents and ketone solvents.

The organic solvent is preferably mixed with water at any desired ratio.

As the organic solvent, for example, compounds given as examples in paragraphs [0139] to [0140] of WO2022/044893A, the contents of which are incorporated herein, can be used.

### <<Physical Properties of Polishing Liquid>>

Hereinafter, the properties of the polishing liquid will be described in detail.

<pH>

The pH of the polishing liquid is 7.0 or more.

For higher polishing efficiency and for the effect of the present invention to be better produced, the pH of the polishing liquid is preferably 7.0 to 14.0, more preferably 8.8 to 11.5, still more preferably 9.0 to 11.0.

The pH of the polishing liquid can be adjusted using the pH adjuster described above.

The pH of the polishing liquid can be measured by a method in accordance with JIS Z 8802-1984 using a known pH meter. The measurement temperature is 25 °C.

### <<Method of Producing Polishing Liquid>>

The method of producing the polishing liquid is not particularly limited, and a known method can be used. For example, the polishing liquid may be produced by mixing the components described above at predetermined concentrations, or may be produced by preparing a concentrate and then diluting the concentrate.

In mixing the components, each component may be mixed in one portion or may be mixed in multiple portions. The components to be mixed may each be in the form of a solid or an aqueous solution.

The stirring device and stirring method used for the mixing are not particularly limited, and a known device and method may be used as a stirrer or a disperser. Examples of the stirrer include industrial mixers, portable stirrers, mechanical stirrers, and magnetic stirrers. Examples of the disperser include industrial dispersers, homogenizers, ultrasonic dispersers, and bead mills.

### <<Washing Liquid>>

Next, components that can be included in the washing liquid and the properties thereof will be described in detail.

The washing liquid includes an amine compound.

### <Amine Compound>

The washing liquid includes an amine compound. The amine compound is an organic compound having an amino group and not having an aromatic heterocycle.

The amino group may be any of a primary amino group (—NH₂), a secondary amino group (>NH), a tertiary amino group (>N—), and a quaternary ammonium salt group. In other words, the amine compound may be any of a primary amine compound, a secondary amine compound, a tertiary amine compound, and a quaternary ammonium compound. When having amino groups in different series, the amine compound is classified as an amine compound in the highest series. The number of amino groups of the amine compound is not particularly limited as long as it is 1 or more, but is preferably 1 to 6, more preferably 1 to 3.

The amine compound may have a substituent other than amino groups, and the substituent is preferably a hydroxy group.

The ClogP value of the amine compound is preferably −2.00 to 2.00, more preferably −1.50 to 1.00, still more preferably 0.00 to 0.60.

In the present specification, the ClogP value is a value determined by calculating the common logarithm logP of 1-octanol/water partition coefficient P. For the calculation of the ClogP value, a known method and software can be used, or a known literature value (e.g., a value reported on a website such as http://www.chemspider.com) may be employed. In the present invention, a value obtained by drawing a structure using ChemDraw Professional (version 20.1.1.125) available from PerkinElmer and making calculations using the software is employed unless otherwise specified.

The amine compound is preferably at least one selected from the group consisting of secondary amine compounds, tertiary amine compounds, and quaternary ammonium compounds, more preferably at least one selected from the group consisting of tertiary amine compounds and quaternary ammonium compounds.

In addition, the amine compound more preferably includes at least one compound selected from the group consisting of a compound represented by formula (A1) described later and a compound represented by formula (A2) described later.

One amine compound may be used alone, or two or more amine compounds may be used in combination. Preferably, two or more amine compounds are used in combination.

### —Primary Amine Compound—

The primary amine compound is an amine compound having only a primary amino group as an amino group. The primary amine compound may be a monoamine compound or a polyamine compound, and is preferably a monoamine compound.

The monoamine compound is preferably a monoamine compound having a hydroxy group; examples include monoethanolamine (MEA), monopropanolamine, and 2-amino-2-methyl-1-propanol (AMP).

Examples of the polyamine compound include ethylenediamine (EDA), 1,3-propanediamine (PDA), 1,2-propanediamine, 1,3-butanediamine, and 1,4-butanediamine.

### —Secondary Amine Compound—

The secondary amine compound is a compound having, in its molecule, at least one secondary amino group.

The secondary amine compound may have a primary amino group as an amino group other than the secondary amino group. The nitrogen atom included in the secondary amino group of the secondary amine compound may be a ring-member atom.

The secondary amine compound may have another substituent in addition to the secondary amino group. The substituent is, for example, a hydroxy group.

The secondary amine compound may have two or more amino groups. That is, the secondary amine compound may be a diamine compound or a polyamine compound.

### —Tertiary Amine Compound—

The tertiary amine compound is a compound having, in its molecule, at least one tertiary amino group. The tertiary amine compound may have at least one of a primary amino group or a secondary amino group as an amino group other than the tertiary amino group, and also preferably has only the tertiary amino group as an amino group (has neither a primary amino group nor a secondary amino group).

The nitrogen atom included in the tertiary amino group of the tertiary amine compound may be a ring-member atom, but for the effect of the present invention to be better produced, the amine compound preferably does not have a ring structure.

The tertiary amine compound may have another substituent in addition to the tertiary amino group. The substituent is, for example, a hydroxy group.

The tertiary amine compound may have two or more tertiary amino groups. That is, the tertiary amine compound may be a diamine compound or a polyamine compound.

The amine compound preferably includes at least one selected from the group consisting of a compound represented by formula (A1), a compound represented by formula (A2), and a compound represented by formula (A3), more preferably includes at least one selected from the group consisting of a compound represented by formula (A1) and a compound represented by formula (A2).

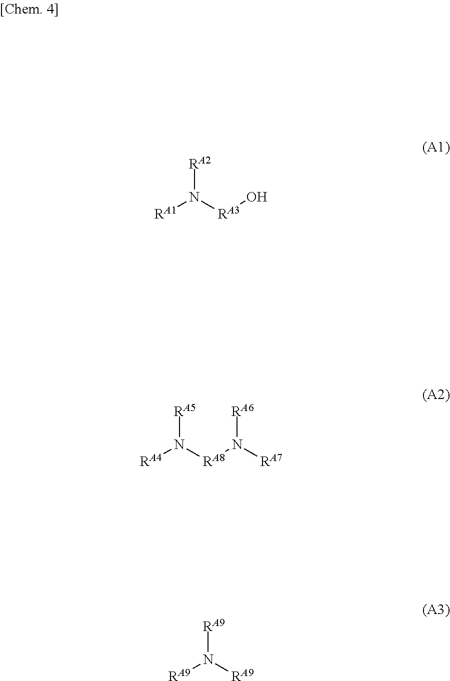

In formula (A1), R^{A1} and R^{A2} each independently represent a hydrogen atom or an optionally substituted alkyl group, provided that at least one of R^{A1} or R^{A2} represents an optionally substituted alkyl group.

R^{A3} represents an optionally substituted alkylene group.

Two of R^{A1} to R^{A3} may be bonded to each other through a single bond or a divalent linking group to form a ring.

R^{A1} and R^{A2} each independently represent a hydrogen atom or an optionally substituted alkyl group.

The alkyl group may be linear, branched, or cyclic.

The number of carbon atoms of the alkyl group is preferably 1 to 30, more preferably 1 to 15, still more preferably 1 to 5, particularly preferably 1 to 3.

The substituent on the alkyl group is, for example, a halogen atom such as a fluorine atom, a chlorine atom, or a bromine atom; an alkoxy group; a hydroxy group; an acyl group such as an acetyl group, a propionyl group, or a benzoyl group; a cyano group; or a nitro group, preferably a hydroxy group.

When the alkyl group has a hydroxy group, the number of hydroxy groups on the alkyl group is preferably 1 to 5, more preferably 1 to 3, still more preferably 1.

In particular, R^{A1} and R^{A2} are each preferably an alkyl group having 1 to 10 carbon atoms that optionally has a hydroxy group, more preferably an alkyl group having 1 to 3 carbon atoms that optionally has a hydroxy group, still more preferably a methyl group, an ethyl group, a propyl group, an isopropyl group, or a 2-hydroxyethyl group.

At least one of R^{A1} or R^{A2} represents an optionally substituted alkyl group. Preferably, R^{A1} and

R^{A2} each represent an optionally substituted alkyl group.

R^{A3} represents an optionally substituted alkylene group.

The alkylene group may be linear, branched, or cyclic.

The number of carbon atoms of the alkylene group is preferably 1 to 10, more preferably 1 to 6, still more preferably 1 to 4.

Examples of the substituent on the alkylene group include the substituents that R^{A1} and R^{A2} may have.

In particular, R^{A3} is preferably an alkylene group having 1 to 6 carbon atoms, more preferably an alkylene group having 1 to 4 carbon atoms, still more preferably a methylene group, an ethylene group, a propylene group, a methylethylene group, an ethylethylene group, a 1-methylpropylene group, a 1,1-dimethylethylene group, or a 1,2-dimethylethylene group, particularly preferably an ethylene group, a methylethylene group, or a 1,1-dimethylethylene group.

Two of R^{A1} to R^{A3} may be bonded to each other through a single bond or a divalent linking group to form a ring. The ring to be formed may be monocyclic or polycyclic.

The divalent linking group is, for example, a divalent hydrocarbon group, —O—, or —CO—, preferably an alkylene group.

Examples of the compound represented by formula (A1) include 2-(dimethylamino)-2-methyl-1-propanol (DMAMP), N-methyldiethanolamine (MDEA), 2-(diisopropylamino) ethanol, 2-(diethylamino) ethanol (DEAE), 2-(dimethylamino) ethanol (DMAE), N-tert-butyldiethanolamine (t-BDEA), N-ethyldiethanolamine (EDEA), 2-(dibutylamino) ethanol, triethanolamine, 1-[bis(2-hydroxyethyl)amino]-2-propanol, 1-methyl-2-piperidine methanol, 4-hydroxy-1,2,2,6,6-pentamethylpiperidine (HOPEMP), 1-piperidine ethanol, 1-methyl-3-piperidine methanol, 1-methyl-3-pyrrolidinol, 3-hydroxy-1-methylpiperidine, 2-(N-methyl)amino-2-methyl-1-propanol) (MAMP), diisopropanolamine, dimethanolamine, diethanolamine, 2-(ethylamino) ethanol, 2-(propylamino) ethanol, N-methylethanolamine (N-MEA), N-butylethanolamine, and N-cyclohexylethanolamine.

In formula (A2), R^{A4} to R^{A7} each independently represent a hydrogen atom or an optionally substituted alkyl group, provided that at least one of R^{A4} to R^{A7} represents an optionally substituted alkyl group.

Two of R^{A4} to R^{A7} may be bonded to each other through a single bond or a divalent linking group to form a ring. R^{A4} and R^{A7}, and R^{A5} and R^{A6}, may each be bonded to each other through a single bond or a divalent linking group to form a ring.

R^{A8} represents an alkylene group that optionally has a hydroxy group and optionally has a linking group represented by —NR^{Ax}— or —O—. R^{Ax} represents a hydrogen atom or an alkyl group.

R^{A4} to R^{A7} each independently represent a hydrogen atom or an optionally substituted alkyl group.

The number of carbon atoms of the alkyl group is preferably 1 to 30, more preferably 1 to 15, still more preferably 1 to 6, particularly preferably 1 to 3.

Examples of the substituent on the alkylene group include the substituents that R^{A1} and R^{A2} may have.

In particular, R^{A4} to R^{A7} are each preferably an alkyl group having 1 to 3 carbon atoms, more preferably a methyl group, an ethyl group, a propyl group, or an isopropyl group, still more preferably a methyl group.

At least one of R^{A4} to R^{A7} represents an optionally substituted alkyl group. Preferably, R^{A3} and R^{A4} each represent an optionally substituted alkyl group. More preferably, R^{A4} to R^{A7} each represent an optionally substituted alkyl group.

R^{A8} represents an alkylene group that optionally has a hydroxy group and optionally has a linking group represented by —NR^{Ax}— or —O—. R^{Ax} represents a hydrogen atom or an alkyl group. The number of carbon atoms of the alkylene group is preferably 1 to 10, more preferably 1 to 8, still more preferably 1 to 6.

When the alkylene group has a hydroxy group, the number of hydroxy groups on the alkylene group is preferably 1 to 5, more preferably 1 to 3, still more preferably 1.

The number of linking groups represented by —NR^{Ax}-on the alkylene group is preferably 0 to 3, more preferably 0 to 1.

The number of linking groups represented by —O— on the alkylene group is preferably 0 to 3, more preferably 0 to 1.

R^{Ax} is preferably a hydrogen atom or an alkyl group having 1 to 3 carbon atoms, more preferably a hydrogen atom, a methyl group, an ethyl group, or an isopropyl group, still more preferably a methyl group.

Two of R^{A4} to R^{A7} may be bonded to each other through a single bond or a divalent linking group to form a ring. The ring to be formed may be monocyclic or polycyclic.

The divalent linking group is, for example, a divalent hydrocarbon group, —O—, or —CO—, preferably an alkylene group.

Examples of the compound represented by formula (A2) include N,N,N′,N″,N″-pentamethyldiethylenetriamine (PMDTA), tetramethyl-1,3-diaminobutane, tetramethyl-1,6-diaminohexane, N,N-diisopropylethylenediamine (DIPEN), N,N-dimethylethylenediamine (DMEN), N,N-diethylethylenediamine, tetramethyl-1,3-diaminopropane, pentamethyldipropylenetriamine, N,N′-diethylethylenediamine (NN′-DEEN), N-(2-hydroxypropyl)ethylenediamine (HPEN), N-ethylethylenediamine (EEN), 1,4-bis(2-hydroxyethyl) piperazine (BHEP), 1,4-bis(2-aminoethyl) piperazine (BAEP), 1,4-bis(3-aminopropyl) piperazine (BAPP), and 1,4-diazabicyclo[2.2.2]octane (DABCO).

In formula (A3), each R^{A9} independently represents an alkyl group.

The alkyl group may be linear, branched, or cyclic.

The number of carbon atoms of the alkyl group is preferably 1 to 30, more preferably 1 to 15, still more preferably 1 to 5, particularly preferably 1 to 3.

Examples of the compound represented by formula (A3) include trimethylamine (TMA) and triethylamine (TEA).

### —Quaternary Ammonium Compound—

The quaternary ammonium compound is preferably a compound having a quaternary ammonium cationic moiety in which a nitrogen atom is bonded to four hydrocarbon groups. The number of carbon atoms of the quaternary ammonium cationic moiety in the quaternary ammonium compound is preferably 4 to 20, more preferably 5 to 15. The number of carbon atoms refers to the total number of carbon atoms included in the quaternary ammonium cationic moiety and does not include the number of carbon atoms in an anion forming a salt.

Examples of the anionic moiety corresponding to the quaternary ammonium cationic moiety include, but are not limited to, a hydroxide ion, halide ions (a chloride ion, a bromide ion, a fluoride ion, and an iodide ion), an acetate ion, a carbonate ion, and a sulfate ion.

The molecular weight of the quaternary ammonium compound is preferably 90 to 1000, more preferably 90 to 500, still more preferably 90 to 300, particularly preferably 90 to 200.

The quaternary ammonium compound is preferably a compound represented by formula (a) below.

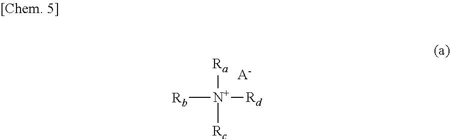

In formula (a), Rₐ to Rₐ each independently represent an optionally substituted alkyl group. The alkyl group may be linear or branched, and is preferably linear. The number of carbon atoms of the alkyl moiety of the alkyl group is preferably 1 to 10, more preferably 1 to 6, still more preferably 1 to 4, particularly preferably 1 or 2.

Examples of the alkyl group include a methyl group, an ethyl group, a propyl group, a butyl group, a pentyl group, a hexyl group, a heptyl group, an octyl group, a nonyl group, a decyl group, an undecyl group, a dodecyl group, a tridecyl group, a tetradecyl group, a pentadecyl group, and a hexadecyl group.

Examples of the substituent include a hydroxy group and a phenyl group. Examples of substituted alkyl groups include a 2-hydroxyethyl group, a 2-hydroxypropyl group, and a benzyl group. The methylene group constituting the alkyl group may be substituted with a divalent substituent such as —O—.

The total number of carbon atoms included in Rₐ to Rₐ is not particularly limited, but is preferably 4 to 20, more preferably 5 to 15.

Two optionally substituted alkyl groups selected from the group consisting of Rₐ to R_{d} may be bonded to each other to form a ring.

In formula (a), A represents a monovalent anion.

The monovalent anion represented by A is, for example, F, Cl⁻, Br⁻, OH, NO₃⁻, CH₃COO⁻, or CH₃CH₂SO₄, preferably F⁻, Cl⁻, Br⁻, or OH⁻, more preferably Cl⁻ or OH⁻, still more preferably OH⁻.

Examples of the quaternary ammonium compound represented by formula (a) include tetramethylammonium salts, tetraethylammonium salts, tetrabutylammonium salts, ethyltrimethylammonium salts, triethylmethylammonium salts, diethyldimethylammonium salts, tributylmethylammonium salts, dimethyl dipropylammonium salts, dodecyltrimethylammonium salts, trimethyltetradecylammonium salts, hexadecyltrimethylammonium salts, benzyltrimethylammonium salts, benzyltriethylammonium salts, (2-hydroxyethyl)trimethylammonium salts (also referred to as “choline”), triethyl(2-hydroxyethyl) ammonium salts, diethyl bis(2-hydroxyethyl) ammonium salts, ethyl tris(2-hydroxyethyl) ammonium salts, and tris(2-hydroxyethyl)methylammonium salts.

The anion included in the above salts is preferably F⁻, Cl⁻, Br⁻, or OH⁻, more preferably C⁻ or OH⁻, still more preferably OH⁻.

In particular, the quaternary ammonium compound is preferably tris(2-hydroxyethyl)methylammonium hydroxide (THEMAH), ethyltrimethylammonium hydroxide (ETMAH), tetramethylammonium hydroxide (TMAH), tetraethylammonium hydroxide (TEAH), tetrabutylammonium hydroxide (TBAH), or (2-hydroxyethyl)trimethylammonium hydroxide.

The amine compound preferably includes at least one selected from the group consisting of DMAMP, MDEA, PMDTA, THEMAH, ETMAH, MAMP, NN′-DEEN, HPEN, EEN, DEAE, DMAE, EDEA, tetramethyl-1,6-diaminohexane, DIPEN, DMEN, TMAH, TEAH, TBAH, and (2-hydroxyethyl)trimethylammonium hydroxide, more preferably includes at least one selected from the group consisting of DMAMP, MDEA, PMDTA, THEMAH, and ETMAH.

For higher organic residue removability, the content of the amine compound is preferably 0.005 mass % or more, more preferably 0.03 mass % or more, still more preferably 0.06 mass % or more, relative to the total mass of the washing liquid. For higher interfacial corrosion suppressibility, the content of the amine compound is preferably 10.0 mass % or less, more preferably 8.0 mass % or less, still more preferably 1.0 mass % or less, particularly preferably 0.6 mass % or less, most preferably 0.2 mass % or less, relative to the total mass of the washing liquid. The content of the amine compound is also preferably 0.005 to 8.0 mass %, more preferably 0.03 to 0.6 mass %, still more preferably 0.06 to 0.2 mass %, relative to the total mass of the washing liquid. For higher organic residue removability, the content of the amine compound is preferably 70.0 mass % or more, more preferably 80.0 mass %, still more preferably 93.0 mass % or more, relative to the total solid contents in the washing liquid. The upper limit is not particularly limited and may be 100 mass %, but is preferably 98.0 mass % or less for higher interfacial corrosion suppressibility.

For higher organic residue removability and higher interfacial corrosion suppressibility, the ratio of the content of the nonionic surfactant relative to the total mass of the polishing liquid to the content of the amine compound relative to the total mass of the washing liquid is preferably 0.01 to 20.00, more preferably 0.04 to 12.00, still more preferably 0.05 to 8.00.

For example, when the content of the amine compound relative to the total mass of the washing liquid is 0.1 mass % and the content of the nonionic surfactant relative to the total mass of the polishing liquid is 0.05 mass %, the above ratio is calculated as (0.05× 10⁻²)/(0.1×10⁻²)=0.50. For higher organic residue removability and higher interfacial corrosion suppressibility, the ratio of the content of the specific azole compound relative to the total mass of the polishing liquid to the content of the amine compound relative to the total mass of the washing liquid is preferably 0.001 to 20.00, more preferably 0.004 to 8.00, still more preferably 0.005 to 0.90. For example, when the content of the amine compound relative to the total mass of the washing liquid is 0.1 mass % and the content of the specific azole compound relative to the total mass of the polishing liquid is 0.05 mass %, the above ratio is calculated as (0.05×10⁻²)/(0.1×10⁻²)=0.50.

When two or more amine compounds are used, their total content is preferably within the above ranges.

### <Anticorrosive>

The washing liquid may include an anticorrosive, and preferably includes an anticorrosive for higher interfacial corrosion suppressibility. The anticorrosive is a compound different from the amine compound described above.

The anticorrosive is not particularly limited as long as it is a compound that suppresses the corrosion of a treatment target, but is preferably an aromatic heterocyclic compound, more preferably a nitrogen-containing aromatic heterocyclic compound.

The nitrogen-containing aromatic heterocyclic compound is, for example, a purine compound or an azole compound, preferably a purine compound.

### —Purine Compound—

The purine compound refers to purine or a purine derivative. The purine compound is preferably a compound represented by any of formulae (C1) to (C4), more preferably a compound represented by formula (C1) or a compound represented by formula (C2), still more preferably a compound represented by formula (C5) or a compound represented by formula (C7).

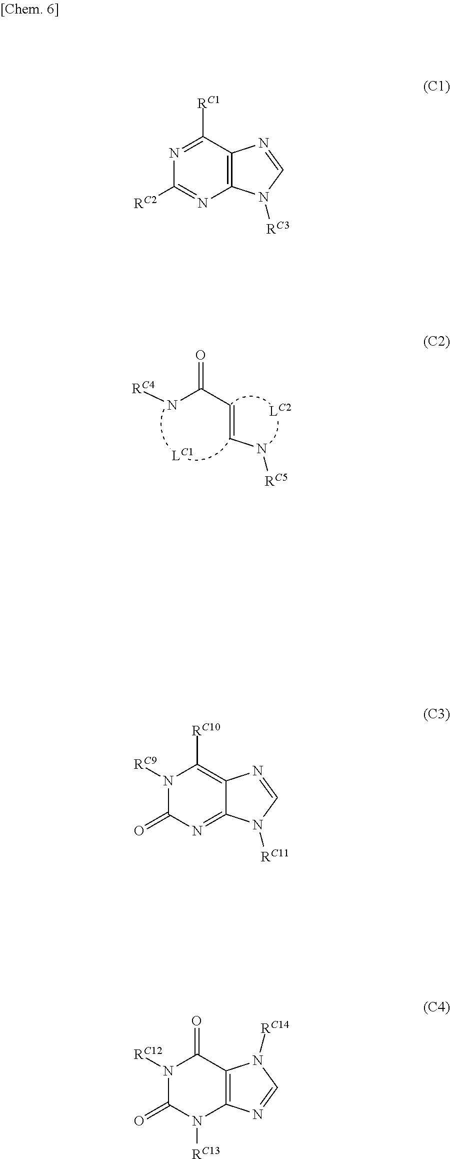

In formula (C1), RC¹ to R^{C3} each independently represent a hydrogen atom, an optionally substituted alkyl group, an optionally substituted amino group, a thiol group, a hydroxy group, a halogen atom, an optionally substituted saccharide group, or an optionally substituted polyoxyalkylene-containing group.

The alkyl group may be linear, branched, or cyclic. The number of carbon atoms is preferably 1 to 10, more preferably 1 to 5, still more preferably 1 to 3.

The saccharide group is, for example, a group derived by removing one hydroxy group from a saccharide selected from the group consisting of monosaccharides, disaccharides, and polysaccharides, preferably a group derived by removing one hydroxy group from a monosaccharide.

Examples of the monosaccharides include pentoses such as ribose, deoxyribose, arabinose, and xylose, trioses, tetroses, hexoses, and heptoses. Pentoses are preferred, ribose, deoxyribose, arabinose, and xylose are more preferred, and ribose and deoxyribose are still more preferred. Examples of the disaccharides include sucrose, lactose, maltose, trehalose, turanose, and cellobiose.

Examples of the polysaccharides include glycogen, starch, and cellulose.

The saccharides may be linear or cyclic, and are preferably cyclic.

Examples of the cyclic saccharides include a furanose ring and a pyranose ring.

The optionally substituted polyoxyalkylene-containing group means a group including an optionally substituted polyoxyalkylene group as a part of the group.

The polyoxyalkylene group constituting the polyoxyalkylene-containing group is, for example, a polyoxyethylene group, a polyoxypropylene group, or a polyoxybutylene group, preferably a polyoxyethylene group.

Examples of substituents on the alkyl group, the amino group, the saccharide group, and the polyoxyalkylene-containing group include hydrocarbon groups such as optionally substituted alkyl groups, aryl groups, and a benzyl group; halogen atoms such as a fluorine atom, a chlorine atom, and a bromine atom; alkoxy groups; a hydroxy group; alkoxycarbonyl groups such as a methoxycarbonyl group and an ethoxycarbonyl group; acyl groups such as an acetyl group, a propionyl group, and a benzoyl group; a cyano group; and a nitro group.

Examples of substituents that the optionally substituted alkyl group may have include the above groups given as examples of substituents, and more specific examples include aryl groups and heteroaryl groups.

R^{C1} is preferably a hydrogen atom or an optionally substituted amino group, more preferably an optionally substituted amino group.

In another preferred embodiment, R^{C1} is preferably an optionally substituted alkyl group, a thiol group, a hydroxy group, a halogen atom, an optionally substituted saccharide group, or an optionally substituted polyoxyalkylene-containing group.

R^{C2} is preferably a hydrogen atom or an optionally substituted alkyl group, more preferably a hydrogen atom.

R^{C3} is preferably a hydrogen atom, an optionally substituted alkyl group, or an optionally substituted saccharide group, more preferably a hydrogen atom or an optionally substituted saccharide group.

In formula (C2), L^{C1} represents —CR^{C6}═N— or —C(═O)—NR^{C7}—. L^{C2} represents —N═CH— or —NR^{C8}— C(═O)—. R^{C4} to R^{C8} each independently represent a hydrogen atom, an optionally substituted alkyl group, an optionally substituted amino group, a thiol group, a hydroxy group, a halogen atom, an optionally substituted saccharide group, or an optionally substituted polyoxyalkylene-containing group.

Examples of the groups represented by R^{C4} to R^{C8} include the examples of the groups represented by R^{C1} to R^{C3} in formula (C1) above.

R^{C4} and R^{C5} are each preferably a hydrogen atom or an optionally substituted alkyl group, more preferably a hydrogen atom.

R_{C6} is preferably a hydrogen atom, an optionally substituted alkyl group, or an optionally substituted amino group, more preferably a hydrogen atom.

L^{C1} is preferably —C(═O)—NR^{C7}—.

R^{C7} is preferably a hydrogen atom or an optionally substituted alkyl group, more preferably a hydrogen atom.

L^{C2} is preferably —N═CH—.

R^{C8} is preferably a hydrogen atom or an optionally substituted alkyl group, more preferably a hydrogen atom.

In formula (C3), R^{C9} to R^{C11} each independently represent a hydrogen atom, an optionally substituted alkyl group, an optionally substituted amino group, a thiol group, a hydroxy group, a halogen atom, an optionally substituted saccharide group, or an optionally substituted polyoxyalkylene-containing group.

Examples of the groups represented by R^{C9} to R^{C11} include the groups represented by R^{C1} to R^{C3} in formula (C1) above.

R^{C9} is preferably a hydrogen atom or an optionally substituted alkyl group, more preferably a hydrogen atom.

R^{C10} is preferably a hydrogen atom, an optionally substituted alkyl group, or an optionally substituted amino group, more preferably a hydrogen atom or an optionally substituted amino group, still more preferably an optionally substituted amino group.

R^{C11} is preferably a hydrogen atom or an optionally substituted alkyl group, more preferably a hydrogen atom.

In formula (C4), R^{C12} to R^{C14} each independently represent a hydrogen atom, an optionally substituted alkyl group, an optionally substituted amino group, a thiol group, a hydroxy group, a halogen atom, an optionally substituted saccharide group, or an optionally substituted polyoxyalkylene-containing group.

Examples of the groups represented by R^{C12} to R^{C14} include the groups represented by R^{C1} to R^{C3} in formula (C1) above.

R^{C12} is preferably a hydrogen atom or an optionally substituted alkyl group, more preferably an optionally substituted alkyl group.

In another preferred embodiment, R^{C12} is preferably an optionally substituted alkyl group, an optionally substituted amino group, a thiol group, a hydroxy group, a halogen atom, an optionally substituted saccharide group, or an optionally substituted polyoxyalkylene-containing group.

R^{C13} is preferably a hydrogen atom or an optionally substituted alkyl group, more preferably an optionally substituted alkyl group.

R^{C14} is preferably a hydrogen atom or an optionally substituted alkyl group.

The compound represented by formula (C1) is preferably a compound represented by formula (C5).

The compound represented by formula (C2) is preferably a compound represented by any of formula (C6) to formula (C8), more preferably a compound represented by formula (C7).

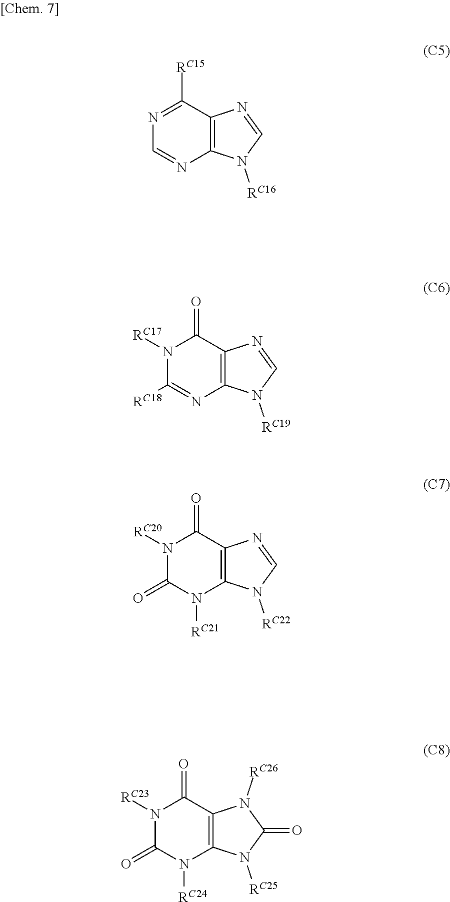

In formula (C5), R^{C15} and R^{C16} each independently represent a hydrogen atom, an optionally substituted alkyl group, an optionally substituted amino group, a thiol group, a hydroxy group, a halogen atom, an optionally substituted saccharide group, or an optionally substituted polyoxyalkylene-containing group.

Examples of the groups represented by R^{C15} and R^{C16} include the groups represented by R^{C1} to R^{C3} in formula (C1) above.

R^{C15} is preferably a hydrogen atom, an optionally substituted alkyl group, or an optionally substituted amino group, more preferably an optionally substituted amino group.

R^{C16} is preferably a hydrogen atom, an optionally substituted alkyl group, or an optionally substituted saccharide group, more preferably a hydrogen atom or an optionally substituted saccharide group, still more preferably a hydrogen atom.

In formula (C6), R^{C17} to R^{C19} each independently represent a hydrogen atom, an optionally substituted alkyl group, an optionally substituted amino group, a thiol group, a hydroxy group, a halogen atom, an optionally substituted saccharide group, or an optionally substituted polyoxyalkylene-containing group.

Examples of the groups represented by R^{C17} to R^{C19} include the groups represented by R^{C1} to R^{C3} in formula (C1) above.

R^{C17} to R^{C19} are each preferably a hydrogen atom or an optionally substituted alkyl group, more preferably a hydrogen atom.

In formula (C7), R^{C20} to R^{C22} each independently represent a hydrogen atom, an optionally substituted alkyl group, an optionally substituted amino group, a thiol group, a hydroxy group, a halogen atom, an optionally substituted saccharide group, or an optionally substituted polyoxyalkylene-containing group.

Examples of the groups represented by R^{C20} to R^{C22} include the groups represented by R^{C1} to R^{C3} in formula (C1) above.

R^{C20} to R^{C22} are each preferably a hydrogen atom or an optionally substituted alkyl group, more preferably a hydrogen atom.

In formula (C8), R^{C23} to R^{C26} each independently represent a hydrogen atom, an optionally substituted alkyl group, an optionally substituted amino group, a thiol group, a hydroxy group, a halogen atom, an optionally substituted saccharide group, or an optionally substituted polyoxyalkylene-containing group.

Examples of the groups represented by R^{C23} to R^{C26} include the groups represented by R^{C1} to R^{C3} in formula (C1) above.

R^{C23} to R^{C26} are each preferably a hydrogen atom or an optionally substituted alkyl group, more preferably a hydrogen atom.

Examples of the purine compound include purine, adenine, xanthine, 6-methylaminopurine(methyladenine), kinetin, 6-benzyladenine, adenosine, hypoxanthine, guanine, theobromine, caffeine, uric acid, isoguanine, enprofylline, theophylline, xanthosine, 7-methylxanthosine, 7-methylxanthine, eritadenine, dimethyladenine, 3-methylxanthine, 1,7-dimethylxanthine, 1-methylxanthine, 1,3-dipropyl-7-methylxanthine, 3,7-dihydro-7-methyl-1H-purine-2,6-dione, 1,7-dipropyl-3-methylxanthine, 1-methyl-3,7-dipropylxanthine, 1,3-dipropyl-7-methyl-8-dicyclopropylmethylxanthine, 1,3-dibutyl-7-(2-oxopropyl) xanthine, 1-butyl-3,7-dimethylxanthine, 3,7-dimethyl-1-propylxanthine, mercaptopurine, 2-aminopurine, nelarabine, vidarabine, 2,6-dichloropurine, aciclovir, N6-benzoyladenosine, trans-zeatin, entecavir, valaciclovir, abacavir, 2′-deoxyguanosine, disodium inosinate, ganciclovir, disodium guanosine 5′-monophosphate, O-cyclohexylmethylguanine, N2-isobutyryl-2′-deoxyguanosine, β-nicotinamide adenine dinucleotide phosphate, 6-chloro-9-(tetrahydropyran-2-yl) purine, clofarabine, 7-(2,3-dihydroxypropyl) theophylline, 6-mercaptopurine, proxyphylline, 2,6-diaminopurine, 2′,3′-dideoxyinosine, theophylline-7-acetic acid, 2-chloroadenine, 2-amino-6-chloropurine, 8-bromo-3-methylxanthine, 2-fluoroadenine, penciclovir, 9-(2-hydroxyethyl) adenine, 7-(2-chloroethyl) theophylline, 2-amino-6-iodopurine, 2-thioxanthine, 2-amino-6-methoxypurine, N-acetylguanine, adefovir dipivoxil, 8-chlorotheophylline, and 6-methoxypurine.

In particular, the purine compound preferably includes at least one selected from the group consisting of adenine, xanthine, methyladenine, kinetin, 6-benzyladenine, adenosine, and hypoxanthine, more preferably includes at least one selected from the group consisting of adenine and xanthine.

For higher interfacial corrosion suppressibility, the content of the anticorrosive is preferably 0.1 mass ppm or more, more preferably 1 mass % ppm or more, still more preferably 15 mass ppm or more, relative to the total mass of the washing liquid. The upper limit is preferably 5.0 mass % or less, more preferably 0.5 mass % or less, still more preferably 0.1 mass % or less.

One anticorrosive may be used alone, or two or more anticorrosives may be used. When two or more anticorrosives are used, their total content is preferably within the above range.

### <Water>

The washing liquid may include water.

The water is not particularly limited as long as it does not affect a semiconductor substrate, and distilled water, ion-exchanged water, and pure water (ultrapure water) can be used. Pure water and ion-exchanged water are preferred because they have less influence on a semiconductor substrate in a manufacturing process of a semiconductor device.

The content of the water may be any amount as long as the water is the balance excluding the components that can be included in the washing liquid.

For the effect of the present invention to be better produced, the content of the water is preferably 70.0 mass % or more, more preferably 80.0 mass % or more, still more preferably 90.0 mass % or more, relative to the total mass of the washing liquid. For the effect of the present invention to be better produced, the upper limit is preferably 99.9999 mass % or less, more preferably 99.99 mass % or less, still more preferably 99.97 mass % or less.

### <Organic Acid>

The washing liquid may include an organic acid. For the effect of the present invention to be better produced, the washing liquid preferably includes an organic acid. The organic acid is a compound different from the amine compound and the anticorrosive described above.

Examples of the organic acid include carboxylic acids such as aliphatic carboxylic acids and aromatic carboxylic acids and phosphonic acids.

The organic acid may be in the form of a salt. The salt is, for example, an inorganic salt.

Examples of the aliphatic carboxylic acids include succinic acid, tartaric acid, maleic acid, oxalic acid, malonic acid, glutaric acid, adipic acid, pimelic acid, sebacic acid, formic acid, citric acid, malic acid, glycolic acid, gluconic acid, heptonic acid, and lactic acid.

Examples of the aromatic carboxylic acids include phenyllactic acid, hydroxyphenyllactic acid, phenylsuccinic acid, phthalic acid, isophthalic acid, terephthalic acid, gallic acid, trimellitic acid, mellitic acid, and cinnamic acid.

Examples of the phosphonic acids include compounds described in paragraphs to of WO2018/020878A and compounds ((co) polymers) described in paragraphs to of WO2018/030006A, the contents of which are incorporated herein.

The content of the organic acid is preferably 0.1 mass ppm to 5.0 mass %, more preferably 1 mass ppm to 1.0 mass %, still more preferably 10 mass ppm to 0.3 mass %, relative to the total mass of the washing liquid.

The content of the organic acid is preferably 0.1 to 10.0 mass %, more preferably 0.5 to 5.0 mass %, still more preferably 1.0 to 3.0 mass %, relative to the total solid contents in the washing liquid.

One organic acid may be used alone, or two or more organic acids may be used. When two or more organic acids are used, their total content is preferably within the above ranges.

### <Other Components>

The washing liquid may include other components other than the components described above. Examples of the other components include surfactants, pH adjusters, organic solvents, polymers, polyhydroxy compounds having a molecular weight of 500 or more, and oxidizing agents.

### —Surfactant—

The surfactant is not particularly limited as long as it is a compound having a hydrophilic group and a hydrophobic group (lipophilic group) in one molecule, and is, for example, a nonionic surfactant or an anionic surfactant.

The surfactant often has at least one hydrophobic group selected from the group consisting of aliphatic hydrocarbon groups, aromatic hydrocarbon groups, and combinations thereof.

The number of carbon atoms of the entire surfactant is preferably 16 to 100.

The nonionic surfactant is, for example, an ester-type nonionic surfactant, an ether-type nonionic surfactant, or an ester ether-type nonionic surfactant, preferably an ether-type nonionic surfactant.

As the nonionic surfactant, for example, compounds given as examples in paragraph of WO2022/044893A, the contents of which are incorporated herein, can also be used.

Examples of the anionic surfactant include phosphoric acid ester-based surfactants having a phosphoric acid ester group, sulfonic acid-based surfactants having a sulfo group, phosphonic acid-based surfactants having a phosphonic acid group, carboxylic acid-based surfactants having a carboxy group, and sulfuric acid ester-based surfactants having a sulfuric acid ester group.

As the anionic surfactant, for example, compounds given as examples in paragraphs to of WO2022/044893A, the contents of which are incorporated herein, can also be used.

The content of the surfactant is preferably 0.0001 to 5.00 mass %, more preferably 0.0005 to 1.00 mass %, still more preferably 0.001 to 0.10 mass %, relative to the total mass of the washing liquid.

The content of the surfactant is preferably 0.1 to 50.0 mass %, more preferably 0.5 to 30.0 mass %, still more preferably 1.0 to 10.0 mass %, relative to the total solid contents in the washing liquid. One surfactant may be used alone, or two or more surfactants may be used. When two or more surfactants are used, their total content is preferably within the above ranges.

### —pH Adjuster—

The washing liquid may include a pH adjuster in order to adjust and maintain the pH of the washing liquid.

The pH adjuster is a basic compound or an acidic compound different from the above-described compounds that can be included in the washing liquid. However, it is permissible to adjust the pH of the washing liquid by adjusting the amounts of the above-described components.

The basic compounds and the acidic compounds usable as the pH adjuster are the same as the pH adjusters that can be included in the polishing liquid.

The content of the pH adjuster can be selected according to the types and amounts of other components and the desired pH of the washing liquid. For example, the content of the pH adjuster is preferably 0.0001 to 10 mass %, more preferably 0.001 to 8 mass %, relative to the total mass of the washing liquid.

The content of the pH adjuster is preferably 0.01 to 80 mass %, more preferably 0.1 to 60 mass %, relative to the total solid contents in the washing liquid.

One pH adjuster may be used alone, or two or more pH adjusters may be used. When two or more pH adjusters are used, their total content is preferably within the above ranges.

### —Organic Solvent—

The washing liquid may include an organic solvent.

The organic solvent may be a known organic solvent; examples include alcohol solvents, glycol solvents, glycol ether solvents, and ketone solvents.

The organic solvent is preferably mixed with water at any desired ratio.

As the organic solvent, for example, compounds given as examples in paragraphs to of WO2022/044893A, the contents of which are incorporated herein, can be used.

### —Polymer—

The polymer may be a water-soluble polymer.

The term “water-soluble polymer” refers to a compound in which two or more structural units are linearly or reticularly linked via covalent bonds and which dissolves at a rate of 0.1 g or more per 100 g of water at 20 °C.

As the polymer, for example, water-soluble polymers described in paragraphs to of JP2016-171294A, the contents of which are incorporated herein, can be used.

The molecular weight (the weight-average molecular weight, in the case where the polymer has a molecular weight distribution) of the polymer is preferably 300 or more, more preferably more than 600, still more preferably 1000 or more, particularly preferably more than 1000, most preferably 2000 or more. The upper limit is preferably 1,500,000 or less, more preferably 1,000,000 or less.

### —Polyhydroxy Compound Having Molecular Weight of 500 or More—

As the polyhydroxy compound, for example, compounds given as examples in paragraphs and of WO2022/014287A, the contents of which are incorporated herein, can be used.

### —Oxidizing Agent—

Examples of the oxidizing agents include peroxides, persulfides (e.g., monopersulfides and dipersulfides), percarbonates, and acids and salts thereof.

Examples of the oxidizing agents include oxidative halides (iodine acid, periodic acids such as metaperiodic acid and orthoperiodic acid, and salts thereof), perboric acid, perborates, cerium compounds, and ferricyanides (e.g., potassium ferricyanide).

### <<Physical Properties of Washing Liquid>>

Hereinafter, the properties of the washing liquid will be described in detail.

<pH>

The washing liquid may be alkaline or acidic.

For the effect of the present invention to be better produced, the pH of the washing liquid is preferably 7.0 to 14.0, more preferably 9.0 to 14.0, still more preferably 9.5 to 13.0.

The pH of the washing liquid can be adjusted using the pH adjuster described above.

The pH of the washing liquid can be measured by a method in accordance with JIS Z 8802-1984 using a known pH meter. The measurement temperature is 25 °C.

### <Metal Content>

The contents (measured as ion concentrations) of metals (e.g., metal elements such as Fe, Co, Na, Cu, Mg, Mn, Li, Al, Cr, Ni, Zn, Sn, and Ag) included as impurities in the washing liquid are each preferably 5 mass ppm or less, more preferably 1 mass ppm or less. In the manufacture of a state-of-the-art semiconductor device, a washing liquid with a higher purity will probably be required, and thus the metal content is still more preferably less than 1 mass ppm, that is, on the order of mass ppb or lower, particularly preferably 100 mass ppb or less, most preferably less than 10 mass ppb. The lower limit is preferably 0.

A method of reducing the metal content is, for example, to perform, at the stage of a raw material to be used in producing the washing liquid or the stage after the production of the washing liquid, a purification treatment such as distillation or filtration using an ion-exchange resin or a filter. Another method of reducing the metal content is, for example, to use, as a container for storing a raw material or the washing liquid produced, a container from which impurities are less likely to leach out, which will be described later. Alternatively, for example, the inner wall of a pipe or the like may be lined with a fluorocarbon resin so as to prevent metal components from leaching out from the pipe during the production of the washing liquid.

### <Coarse Particles>

The washing liquid may include coarse particles, but the content thereof is preferably low. A coarse particle means a particle that has a diameter (particle diameter) of 0.03 μm or more when regarded as having a spherical shape.

The coarse particles included in the washing liquid are those finally existing in the form of particles without dissolving in the washing liquid which are derived from particles of dust, motes, organic solids, inorganic solids, and the like included as impurities in raw materials and particles of dust, motes, organic solids, inorganic solids, and the like incorporated as contaminants during the preparation of the washing liquid.

For the content of the coarse particles in the washing liquid, the content of particles having a particle diameter of 0.1 μm or more is preferably 10,000 or less, more preferably 5000 or less, per milliliter of the washing liquid. The lower limit is preferably 0 or more, more preferably 0.01 or more, per milliliter of the washing liquid.

The content of the coarse particles present in the washing liquid can be measured in a liquid phase by using a commercially available measuring apparatus in a light scattering in-liquid particle measurement mode using a laser as a light source.

Examples of the method of removing the coarse particles include purification treatments such as filtering described later.

### <<Method of Producing Washing Liquid>>

The washing liquid can be produced by a known method. Hereinafter, a method of producing the washing liquid will be described in detail.

### <Liquid Preparation Step>

The washing liquid can be produced by, for example, mixing the components described above. The washing liquid may be prepared, for example, by sequentially adding the components described above to a container containing purified pure water, and then mixing them with stirring while adding a pH adjuster as needed to adjust the pH of the mixed solution. When water and the components are added to the container, they may be added in one portion or may be added in multiple portions.

For the stirring device and stirring method used to prepare the washing liquid, a known device may be used as a stirrer or a disperser. Examples of the stirrer include industrial mixers, portable stirrers, mechanical stirrers, and magnetic stirrers. Examples of the disperser include industrial dispersers, homogenizers, ultrasonic dispersers, and bead mills.

### <Purification>

At least one of the raw materials for preparing the washing liquid is preferably subjected to a purification treatment in advance. Examples of the purification treatment include known methods such as distillation, ion exchange, and filtration (filtering).

The purification is preferably performed until the raw material has a purity of 99 mass % or more, more preferably performed until the raw material has a purity of 99.9 mass % or more. The upper limit is preferably 99.9999 mass % or less.

Examples of the method of the purification treatment include passing the raw material through an ion-exchange resin, a reverse osmosis membrane (RO membrane), or the like, distillation of the raw material, and filtering described later.

The purification treatment may be a combination of two or more of the above purification methods. For example, after primary purification in which the raw material is passed through an RO membrane is performed, secondary purification in which the raw material is passed through a purification device including a cation-exchange resin, an anion-exchange resin, or a mixed-bed ion-exchange resin may be performed.

The purification treatment may be performed multiple times.

The filter used in filtering is not particularly limited as long as it has been conventionally used for filtration and other applications. Examples include filters formed of fluorocarbon resins such as polytetrafluoroethylene (PTFE) and tetrafluoroethylene-perfluoroalkyl vinyl ether copolymer (PFA), polyamide resins such as nylon, and polyolefin resins (including high-density or ultrahigh-molecular-weight polyolefin resins) such as polyethylene and polypropylene (PP). Of these materials, materials selected from the group consisting of polyethylene, polypropylene (including high-density polypropylene), fluorocarbon resins (including PTFE and PFA), and polyamide resins (including nylon) are preferred, and fluorocarbon resin filters are more preferred. By performing filtration of the raw material using a filter formed of such a material, highly polar foreign substances which are likely to cause defects can be effectively removed.

### <Container>

The washing liquid (including the form of a diluted washing liquid described later), unless its corrosiveness or the like presents a problem, can be stored, transported, and used while being filled in any desired container. The container is preferably a container having the following features for semiconductor applications: the cleanliness class in the container is high, and impurities are less likely to leach out from the inner wall of a housing portion of the container into the liquid. Examples of such containers include, but are not limited to, various containers commercially available as containers for semiconductor washing liquids, such as “CLEAN Bottle” series manufactured by Aicello Corporation and “Pure bottle” manufactured by Kodama Plastics Co., Ltd.

As the container, containers given as examples in paragraphs to of WO2022/004217A, the contents of which are incorporated herein, can also be used.

These containers are preferably washed inside before being filled with the washing liquid. Preferably, the amount of metal impurities in a liquid used for washing is reduced. The washing liquid, after being produced, may be bottled in a container such as a gallon bottle or a coated bottle, and transported and stored.

To prevent changes in components in the washing liquid during storage, the container may be purged with an inert gas (e.g., nitrogen or argon) having a purity of 99.99995 vol % or more. In particular, a gas with a low water content is preferred. During the transportation and storage, the temperature may be room temperature, and to prevent deterioration, the temperature may be controlled in the range of −20 °C to 20 °C.

### <Clean Room>

Production of the washing liquid, opening and washing of the container, handling such as filling of the washing liquid, treatment analysis, and measurement are preferably all performed in a clean room. The clean room preferably meets 14644-1 clean room standards. The clean room preferably meets any one of International Organization for Standardization (ISO) class 1, ISO class 2, ISO class 3, and ISO class 4, more preferably meets ISO class 1 or ISO class 2, still more preferably meets ISO class 1.

### <Dilution Step>

The washing liquid may be subjected to a dilution step of diluting the washing liquid with a diluent such as water and then used for the treatment of a treatment target in the form of a washing liquid that has been diluted (a diluted washing liquid).

The diluted washing liquid is one form of the washing liquid as long as the requirements of the present invention are satisfied.

The diluent used in the dilution step is preferably subjected to a purification treatment in advance. It is more preferable to perform a purification treatment on the diluted washing liquid obtained by the dilution step.

Examples of the purification treatment include ionic component reduction using an ion-exchange resin, an RO membrane, or the like and foreign matter removal using filtering, which have been described as the purification treatments on the washing liquid, and any one of these treatments is preferably performed.

The dilution ratio of the washing liquid in the dilution step may be appropriately adjusted according to the types and contents of the components and the treatment target to be treated, and the ratio of the diluted washing liquid to the washing liquid before dilution (dilution factor) in terms of mass ratio or volume ratio (volume ratio at 23 °C) is preferably 10-to 10,000-fold, more preferably 20- to 3000-fold, still more preferably 30- to 1000-fold, particularly preferably 30 to 150-fold.

For higher washing performance, the washing liquid is preferably diluted with water.

The change in pH before and after dilution (the difference between the pH of the washing liquid before dilution and the pH of the diluted washing liquid) is preferably 2.0 or less, more preferably 1.8 or less, still more preferably 1.5 or less.

The pH of the washing liquid before dilution and the pH of the diluted washing liquid are each preferably in the above preferred range.

Specifically, the dilution step of diluting the washing liquid may be performed according to the above step of preparing the washing liquid. Also for the stirring device and stirring method used in the dilution step, any of the known stirring devices listed in the above step of preparing the washing liquid may be used.

### {Method of Producing Kit}

The method of producing the kit is not particularly limited. For example, the kit can be produced by producing the polishing liquid and the washing liquid described above and then putting them in different receptacles. As the receptacles, for example, the containers for the washing liquid described above can be used.

### {Method for Manufacturing Semiconductor Device}

The kit according to the present invention is for use in subjecting a treatment target to chemical mechanical polishing and further washing the treatment target subjected to chemical mechanical polishing. In particular, the kit is suitable for use in a method for manufacturing a semiconductor device.

Examples of the method for manufacturing a semiconductor device include, but are not limited to, a method including a step 1 of subjecting a treatment target to chemical mechanical polishing using the polishing liquid, and a step 2, after the step 1, of washing the treatment target subjected to chemical mechanical polishing using the washing liquid.

### <<Step 1>>

The step 1 is a step of subjecting a treatment target to chemical mechanical polishing using the polishing liquid described above.

The treatment target is, for example, a treatment target having a metal, preferably a semiconductor substrate having a metal.

When the semiconductor substrate has a metal, the metal may be located at any position, for example, on the top, bottom, and side surfaces and in the grooves of the semiconductor substrate. When the semiconductor substrate has a metal, the metal may not only be located directly on a surface of the semiconductor substrate, but also be located on the semiconductor substrate with another layer interposed therebetween.

The metal is, for example, at least one metal M selected from the group consisting of copper (Cu), cobalt (Co), ruthenium (Ru), aluminum (Al), tungsten (W), titanium (Ti), tantalum (Ta), chromium (Cr), hafnium (Hf), osmium (Os), platinum (Pt), nickel (Ni), manganese (Mn), iron (Fe), zirconium (Zr), molybdenum (Mo), palladium (Pd), lanthanum (La), and iridium (Ir), preferably Cu, Co, or Ru, more preferably Cu. That is, the treatment target is preferably a treatment target including Cu.

The metal may be any substance including a metal (metal atom); examples include a simple substance of the metal M and an alloy including the metal M.

The treatment target may have, in addition to the above, various layers and/or structures as desired. For example, when the treatment target is a semiconductor substrate, the treatment target may have members such as a barrier layer (e.g., a layer including a barrier metal such as titanium (Ti), titanium nitride (TiN), tantalum (Ta), tantalum nitride (TaN), cobalt (Co), or ruthenium (Ru)), a metal wiring line, an oxide film, a gate electrode, a source electrode, a drain electrode, an insulating layer, a ferromagnetic layer, an integrated circuit structure, and/or a nonmagnetic layer.

The type of the substrate used as the treatment target is not particularly limited; examples include various substrates such as semiconductor wafers, glass substrates for photo masks, glass substrates for liquid crystal display, glass substrates for plasma display, substrates for field emission display (FED), substrates for optical disks, substrates for magnetic disks, and substrates for magneto-optical disks.

The size, thickness, shape, and layer structure of the substrate are not particularly limited and can be appropriately selected as desired.

Examples of the wafer constituting the semiconductor substrate include wafers made of silicon-based materials, such as silicon (Si) wafers, silicon carbide (SiC) wafers, and silicon-containing resin-based wafers (glass epoxy wafers), gallium phosphorus (GaP) wafers, gallium arsenide (GaAs) wafers, and indium phosphorus (InP) wafers.

Examples of the silicon wafers include n-type silicon wafers doped with pentavalent atoms (e.g., phosphorus (P), arsenic (As), and antimony (Sb)) and p-type silicon wafers doped with trivalent atoms (e.g., boron (B) and gallium (Ga)). Examples of silicon of the silicon wafers include amorphous silicon, monocrystalline silicon, polycrystalline silicon, and polysilicon.

In particular, wafers made of silicon-based materials, such as silicon wafers, silicon carbide wafers, and silicon-containing resin-based wafers (glass epoxy wafers), are preferred.

The insulating film is, for example, a silicon oxide film (e.g., a silicon dioxide (SiO₂) film or a tetraethyl orthosilicate (Si(OC₂H₅)₄) film (TEOS film)), a silicon nitride film (e.g., silicon nitride (Si₃N₄) or silicon nitride carbide (SiNC)), or a low-dielectric constant (Low-k) film (e.g., a carbon-doped silicon oxide (SiOC) film or a silicon carbide (SiC) film), preferably a low-dielectric constant (Low-k) film.

The metal wiring film is preferably a copper-containing film, a cobalt-containing film, or a ruthenium-containing film.

Examples of the copper-containing film include wiring films (copper wiring films) made only of metallic copper and alloy wiring films (copper alloy wiring films) made of metallic copper and other metals.

Examples of the copper alloy wiring films include alloy wiring films made of copper and at least one metal selected from the group consisting of Al, Ti, Cr, Mn, Ta, and W. More specific examples include copper-aluminum alloy wiring films (Cu—Al alloy wiring films), copper-titanium alloy wiring films (Cu—Ti alloy wiring films), copper-chromium alloy wiring films (Cu—Cr alloy wiring films), copper-manganese alloy wiring films (Cu—Mn alloy wiring films), copper-tantalum alloy wiring films (Cu—Ta alloy wiring films), and copper-tungsten alloy wiring films (Cu—W alloy wiring films).

Examples of the cobalt-containing film include metal films made only of metallic cobalt (cobalt metal films) and alloy metal films made of metallic cobalt and other metals (cobalt alloy metal films).

Examples of the cobalt alloy metal films include alloy metal films made of cobalt and at least one metal selected from the group consisting of Ti, Cr, Fe, Ni, Mo, Pd, Ta, and W. More specific examples include cobalt-titanium alloy metal films (Co—Ti alloy metal films), cobalt-chromium alloy metal films (Co—Cr alloy metal films), cobalt-iron alloy metal films (Co—Fe alloy metal films), cobalt-nickel alloy metal films (Co—Ni alloy metal films), cobalt-molybdenum alloy metal films (Co—Mo alloy metal films), cobalt-palladium alloy metal films (Co—Pd alloy metal films), cobalt-tantalum alloy metal films (Co—Ta alloy metal films), and cobalt-tungsten alloy metal films (Co—W alloy metal films).

The washing liquid is useful for substrates having cobalt-containing films. Of the cobalt-containing films, a cobalt metal film is often used as a wiring film, and a cobalt alloy metal film is often used as a barrier metal.

Examples of the ruthenium-containing film include metal films made only of metallic ruthenium (ruthenium metal films) and alloy metal films made of metallic ruthenium and other metals (ruthenium alloy metal films). The ruthenium-containing film is often used as a barrier metal.

The method of forming the insulating film, the copper-containing film, the cobalt-containing film, and the ruthenium-containing film on the wafer constituting the semiconductor substrate is not particularly limited as long as it is a method commonly used in this field.

Examples of the method of forming the insulating film include a method in which the wafer constituting the semiconductor substrate is heat treated in the presence of oxygen gas to form a silicon oxide film, and then a gas of silane and ammonia is allowed to flow to form a silicon nitride film by chemical vapor deposition (CVD).

Examples of the method of forming the copper-containing film, the cobalt-containing film, and the ruthenium-containing film include a method in which a circuit is formed on the wafer having the above insulating film by a known method such as resist patterning, and then the copper-containing film, the cobalt-containing film, and the ruthenium-containing film are formed by methods such as plating and CVD.

The step 1 is a step of subjecting the treatment target described above to chemical mechanical polishing (CMP) using the polishing liquid described above.

The CMP can be performed, for example, in such a manner that while the polishing liquid described above is fed to a polishing pad attached to a polishing platen, the treatment target and the polishing pad are slid relative to each other with a surface to be polished of the treatment target being in contact with the polishing pad.

The CMP can be performed using a known chemical mechanical polishing apparatus (hereinafter also referred to as a “CMP apparatus”).

The CMP apparatus may be, for example, a commonly used CMP apparatus having a holder for holding the treatment target having a surface to be polished and a polishing platen to which a polishing pad (provided with, for example, a motor with variable rotation speed) is attached. The polishing pad is not particularly limited, and may be, for example, a commonly used nonwoven fabric, polyurethane foam, or a porous fluorocarbon resin.

The polishing pressure during the CMP is often selected from the range of 10 to 980 hPa, and is preferably 30 to 250 hPa, more preferably 65 to 160 hPa, where the occurrence of scratch defects and irregularities on the polished surface can be suppressed. The polishing pressure means a pressure generated on the contact surface between the surface to be polished and the polishing pad.

The rotation speed of the polishing platen during the CMP is often selected from the range of 10 to 400 rpm, and is preferably 50 to 200 rpm, more preferably 60 to 160 rpm.

To move the treatment target and the polishing pad relative to each other, the holder may be rotated and/or oscillated, the polishing platen may be rotated in a planetary manner, or a belt-like polishing pad may be linearly moved in a single longitudinal direction. The holder may be in a fixed state, a rotating state, or an oscillating state. These polishing methods can be appropriately selected according to the surface to be polished and/or the polishing apparatus.

In the CMP, while the surface to be polished is polished, the polishing liquid is preferably fed continuously to the polishing pad on the polishing platen with a pump or the like. The feed amount of the polishing liquid is not limited, but the surface of the polishing pad is preferably always covered with the polishing liquid.

The feed rate of the polishing liquid is preferably 10 to 1000 mL/min, more preferably 170 to 500 mL/min, where the occurrence of scratch defects and irregularities on the polished surface can be suppressed.

The CMP may be performed only once or twice or more. When the CMP is performed twice or more, the polishing conditions, such as the polishing pressure, the polishing rate, and the feed rate of the polishing liquid, and the polishing liquid used may each be the same or varied.

### <<Step 2>

The step 2 is a step, after the step 1, of washing the treatment target subjected to chemical mechanical polishing using the washing liquid described above.

The washing treatment can be performed by a known method, such as bringing the treatment target and the washing liquid into contact with each other.

The method of bringing the treatment target and the washing liquid into contact with each other is not particularly limited; examples include immersing the treatment target into the washing liquid placed in a tank, spraying the washing liquid onto the treatment target, pouring the washing liquid over the treatment target, and combinations thereof. These methods may be appropriately selected depending on the intended use.

For the above method, a system usually performed in this field may be appropriately employed. For example, scrub washing in which a washing member such as a brush is brought into physical contact with the surface of the treatment target to remove residues and the like while the washing liquid is fed, or the spin (drop) system in which the washing liquid is dropped while the treatment target is rotated may be employed. In the immersion system, the treatment target immersed in the washing liquid is preferably subjected to ultrasonic treatment because impurities remaining on the surface of the treatment target can be further reduced.

The treatment target and the washing liquid may be brought into contact with each other only once or twice or more. When they are brought into contact with each other twice or more, the same method may be repeated, or different methods may be used in combination.

The method of the washing treatment may be a single-wafer method or a batch method.

The single-wafer method is generally a method in which treatment targets are treated one by one, and the batch method is generally a method in which a plurality of treatment targets are simultaneously treated.

The temperature of the washing liquid is not particularly limited as long as it is a temperature usually used in this field. The washing is typically performed at room temperature (about 25 °C), but the temperature can be freely selected from the viewpoint of improving defect removability and preventing damage to members. For example, the temperature of the washing liquid is preferably 10 °C to 60 °C, more preferably 15 °C to 50 °C.

The time of contact between the treatment target and the washing liquid can be appropriately varied according to the types and contents of the components included in the washing liquid and the intended target and use of the washing liquid. Practically, the time is preferably 10 to 120 seconds, more preferably 20 to 90 seconds, still more preferably 30 to 60 seconds.

The feed amount (feed rate) of the washing liquid is preferably 50 to 5000 mL/min, more preferably 500 to 2000 mL/min.

When the treatment target and the washing liquid are brought into contact with each other, a mechanical stirring method may be used in order to enhance the treatment capacity of the washing liquid.

Examples of the mechanical stirring method include circulating the washing liquid on the treatment target, flowing or spraying the washing liquid over or onto the treatment target, and stirring the washing liquid with ultrasonic or megasonic waves.

### <<Other Steps>>

The method for manufacturing a semiconductor device according to the present invention may have other steps other than the steps described above. Examples of the other steps include a pad washing step, a rinsing step, and a drying step.

### <Pad Washing Step>

The pad washing step is a step, between the step 1 and the step 2, of reducing residues present on the treatment target surface using a pad. Specifically, the surface of the treatment target subjected to CMP and the pad are brought into contact with each other, and while a composition for pad washing is fed to the part of contact, the treatment target and the pad are slid relative to each other. As a result, the residues on the surface of the treatment target are removed under the frictional force of the pad and the chemical action of the composition for pad washing.

The pad is not particularly limited and can be appropriately selected according to the type of the treatment target, the type of the residue to be removed, and the apparatus used. The pad may be, for example, a polishing pad used in CMP, or may be a buff pad such as a polyurethane foam buff pad, a nonwoven fabric, a suede buff pad, or a sponge. The pad washing treatment using a pad includes a treatment called buff washing or buff polishing.

As the composition for pad washing, a known composition for washing can be used according to the type of the treatment target and the type and amount of the residue to be removed. Examples of components included in the composition for pad washing include water-soluble polymers such as polyvinyl alcohol, dispersion media such as water, and acids such as nitric acid. The washing liquid included in the kit can be used as the composition for pad washing. The composition for pad washing does not include an abrasive grain.

The apparatus and conditions used in the pad washing treatment can be appropriately selected from known apparatuses and conditions according to the type of the treatment target and the type and amount of the residue to be removed. For example, a treatment method described in paragraphs to of WO2017/169539A, the contents of which are incorporated herein, can be used.

It is also preferable to perform the pad washing treatment using, as the composition for pad washing, a liquid obtained by removing the abrasive grain from the polishing liquid of the kit or the washing liquid of the kit. The washing liquid used in the pad washing treatment may be a diluted washing liquid.

### <Rinsing Step>

The rinsing step is a step of bringing the treatment target and a rinsing liquid into contact with each other. By performing the rinsing step, the treatment target can be washed with the rinsing liquid to efficiently remove defects on the treatment target surface.

The rinsing step is preferably performed subsequently to the step 2.

The rinsing step is preferably a step of rinsing the treatment target using the rinsing liquid. The rinsing step may be performed using any of the above mechanical stirring methods.

Examples of the rinsing liquid include water (preferably DI water), methanol, ethanol, isopropyl alcohol (IPA), N-methylpyrrolidinone, γ-butyrolactone, dimethylsulfoxide, ethyl lactate, and propylene glycol monomethyl ether acetate. An aqueous rinsing liquid having a pH of more than 8.0 (e.g., diluted aqueous ammonium hydroxide) may also be used.

The rinsing liquid can be brought into contact with the treatment target by any of the above-described methods by which the washing liquid is brought into contact with the treatment target. The time of contact between the treatment target and the rinsing liquid can be appropriately varied according to the types and contents of the components included in the washing liquid and the intended target and use of the washing liquid. Practically, the time is preferably 10 to 120 seconds, more preferably 20 to 90 seconds, still more preferably 30 to 60 seconds.

### <Drying Step>

The drying step is a step of drying the treatment target. By performing the drying step, liquid components on the treatment target surface can be removed, and defects in subsequent steps can be reduced.

The drying step is preferably performed after the step 2 or the rinsing step, and when the present manufacturing process has the rinsing step, the drying step is more preferably performed after the rinsing step.

Examples of the method of drying include spin drying, flowing a dry gas over the treatment target, heating the substrate by heating means such as a hot plate or an infrared lamp, marangoni drying, rotagoni drying, isopropyl alcohol (IPA) drying, and any combination thereof.

### <Other Manufacturing Steps>

The present manufacturing method may be performed in combination before or after other steps performed on the substrate in manufacturing an electronic device.

Examples of the other manufacturing steps include steps of forming structures such as a metal wiring line, a gate structure, a source structure, a drain structure, an insulating film, a ferromagnetic layer, and a nonmagnetic layer (e.g., layer formation, etching, chemical mechanical polishing, and modification), steps of forming, exposing, and removing a resist, a heat treatment step, a washing step, and an inspection step.

The present manufacturing method may be performed at any stage during the back end of the line (BEOL) process, the middle of the line (MOL) process, and the front end of the line (FEOL) process, and is preferably performed during the front end of the line process or the middle of the line process.

### EXAMPLES

The present invention will now be described in more detail with reference to Examples.

The materials, amounts, proportions, treatments, treatment procedures, etc. given in the following Examples may be changed as appropriate without departing from the spirit of the present invention. Thus, the scope of the present invention should not be construed as being limited by the Examples given below.

In the following Examples, the pH of polishing liquids and washing liquids was measured using a pH meter (manufactured by Horiba, Ltd., model “F-74”) at 25 °C in accordance with JIS Z 8802-1984.

In the production of washing liquids of Examples and Comparative Examples, handling of containers and preparation, filling, storage, and analytical measurement of washing liquids were all performed at 23 °C in a clean room at a level satisfying ISO Class 2 or lower.

### {Preparation of Members}

### <<Preparation of Polishing Liquid>>

The following raw materials (abrasive grain, nonionic surfactant, specific azole compound, and other components) and water were mixed at compositional ratios shown in Tables to prepare polishing liquids of Examples and Comparative Examples. The pH shown in Tables was adjusted by adding nitric acid and/or potassium hydroxide as a pH adjuster as needed. The balance of each polishing liquid excluding the components shown in Tables is water and a pH adjuster. The content of the pH adjuster was less than 1 mass % in each of Examples and Comparative Examples.

### <Abrasive Grain>

PL-1 (colloidal silica, manufactured by Fuso Chemical Co., Ltd.; average particle diameter, 15 nm)
PL-3 (colloidal silica, manufactured by Fuso Chemical Co., Ltd.; average particle diameter, 60 nm)
PL-5 (colloidal silica, manufactured by Fuso Chemical Co., Ltd.; average particle diameter, 90 nm)
PL-10 (colloidal silica, manufactured by Fuso Chemical Co., Ltd.; average particle diameter, 200 nm)

The average particle diameter is a value measured using a nanoparticle analyzer nanoPartica SZ-100V2 (manufactured by Otsuka Electronics Co., Ltd.).

### <Nonionic Surfactant>

S-1 (LF-EP-61, manufactured by Verdant Specialty Solutions, alcohol alkoxylate)
S-2 (LF-EP-40, manufactured by Verdant Specialty Solutions, alcohol alkoxylate)
S-3 (Surfynol 440, manufactured by Evonik Industries AG)
S-4 (Surfynol MD20, manufactured by Evonik Industries AG)
S-5 (EMULGEN 106, manufactured by Kao Corporation, alcohol alkoxylate)
S-6 (EMULGEN 404, manufactured by Kao Corporation, alcohol alkoxylate)
S-7 (RHEODOL TW-S320V, manufactured by Kao Corporation)
S-8 (RHEODOL 430V, manufactured by Kao Corporation)

### <Specific Azole Compound>

BTA (benzotriazol)
MBTA (5-methylbenzotriazole)
CBTA (5-chlorobenzotriazole)
BBTA (5-butylbenzotriazole)
Compound A (the following compound, a compound represented by formula (I))
Compound B (the following compound, a compound represented by formula (II))
Compound C (the following compound, a compound represented by formula (I))

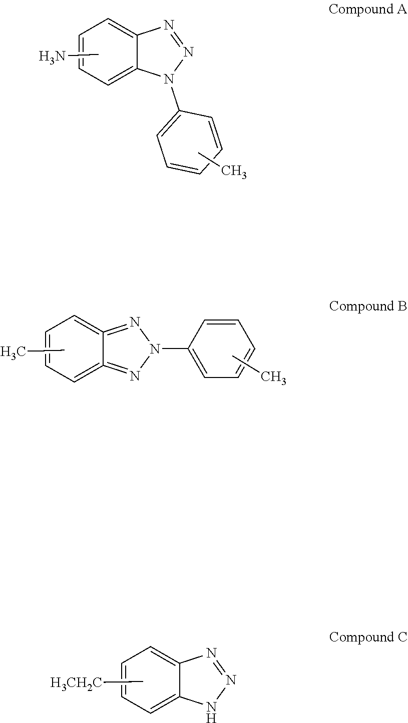

### <Organic Acid>

Citric acid
Malonic acid
EDTPO (ethylenediamine tetra(methylenephosphonic acid))

### <Alcohol>

Methanol
Ethanol
Isopropanol
1-Propanol

### <Oxidizing Agent>

Hydrogen peroxide

### <<Preparation of Washing Liquid>>

The following raw materials (amine compound and other components) and water were mixed at compositional ratios shown in Tables to prepare concentrates. The balance of each washing liquid concentrate excluding the components shown in Tables is water.

Furthermore, the concentrates were diluted with ultrapure water as a diluent at dilution factors (by volume) shown in Tables to prepare washing liquids of Examples and Comparative Examples. The pH of the washing liquids shown in Tables was adjusted by adding nitric acid and/or potassium hydroxide as a pH adjuster as needed. The content of the pH adjuster was less than 1 mass % in each of Examples and Comparative Examples.

### <Amine Compound>

DMAMP (2-(dimethylamino)-2-methyl-1-propanol, a compound represented by formula (A1)) PMDTA (N,N,N′,N″,N″-pentamethyldiethylenetriamine, a compound represented by formula (A2))
MDEA (N-methyldiethanolamine, a compound represented by formula (A1))
THEMAH (tris(2-hydroxyethyl)methylammonium hydroxide)
ETMAH (ethyltrimethylammonium hydroxide)

### <Anticorrosive>

Adenine (a compound represented by formula (C5))
Xanthine (a compound represented by formula (C7))

### <Other Components>

Succinic acid (organic acid)

### {Evaluations}

Using the polishing liquids and the washing liquids of Examples and Comparative Examples, the following evaluations were performed.

### <<Preparation of Treatment Target>>

Treatment targets used in the evaluations were each prepared by bulk-polishing a 12 inch wafer (MIT754 (Cu/Ta/TaN/SiOC (corresponding to BDII) configuration)) having a copper (Cu) wiring pattern according to the following procedure.

The bulk-polishing conditions are shown below.

Using an apparatus “FREX-300X” manufactured by Ebara Corporation as a polishing apparatus, the wafer was bulk-polished under the following conditions while a slurry (CSL9044C (manufactured by FUJIFILM Corporation)) was fed.

### (Polishing Condition)

Table rotation speed: 80 rpm
Head rotation speed: 78 rpm
Polishing pressure: 140 hPa
Polishing pad: manufactured by Rodel Nitta Co., Ltd. VP6000
Polishing liquid feed rate: 250 ml/L
Polishing time: the time taken to reach a polishing endpoint, which is the point at which a signal at the time of exposure of a barrier surface falls below a certain level, plus 20 seconds, for which overpolishing is performed.

### <<Evaluation of Scratch Suppressibility>>

While each of the polishing liquids of Examples and Comparative Examples prepared according to the above procedure was fed, the treatment target prepared in Preparation of Treatment Target above was polished under the following conditions.

### (Polishing Condition)

Table rotation speed: 80 rpm
Head rotation speed: 78 rpm
Polishing pressure: 105 hPa
Polishing pad: manufactured by Fuji Spinning Co., Ltd.H800

Polishing liquid feed rate: 200 ml/L
Polishing time: 30 seconds

After completion of the polishing, the polished surface of the treatment target subjected to polishing was subjected, using each of the washing liquids of Examples and Comparative Examples prepared according to the above procedure, to single-wafer washing by brush scrubbing for 30 seconds in a washing unit 1 of the above polishing apparatus, and further to single-wafer washing by brush scrubbing for 30 seconds in a washing unit 2. After being rinsed with pure water for 60 seconds, the treatment target was spin-dried at a rotational speed of 1000 rpm while nitrogen gas was blown onto the wafer surface in a drying unit, whereby a treatment target for evaluation was obtained.

Thereafter, the number of defects on the surface of the treatment target was determined using a defect inspection apparatus (ComPlus II, manufactured by AMAT). Subsequently, the defect type was identified using Review SEM/EDX (manufactured by Hitachi High-Technologies Corporation), and from the number of scratches observed, scratch suppressibility was evaluated according to the following evaluation criteria. The scratch was defined as a linear defect having a length of 0.5 μm or more. “Number/Wf” in the following means the number of defects per wafer. The scratch suppressibility is preferably D or higher.

### (Evaluation Criteria)

A: The total number of scratches on the wafer was less than 5/Wf.
B: The total number of scratches on the wafer was 5/Wf or more and less than 10/Wf.
C: The total number of scratches on the wafer was 10/Wf or more and less than 15/Wf.
D: The total number of scratches on the wafer was 15/Wf or more and less than 20/Wf.
E: The total number of scratches on the wafer was 20/Wf or more.

### <<Evaluation of Organic Residue Removability>>

For the polished surface of the treatment target for evaluation obtained in Evaluation of Scratch Suppressibility above, the number of organic residues was determined using a defect inspection apparatus (ComPlus II, manufactured by AMAT). Furthermore, organic residues (residues composed mainly of organic matter) with a size of 60 nm or more were identified using Review SEM/EDX, and organic residue removability was evaluated according to the following evaluation criteria. “Number/Wf” in the following means the number of defects per wafer. The organic residue removability is preferably D or higher.

### (Evaluation Criteria)

A: The total number of organic residues on the wafer was less than 50/Wf.
B: The total number of organic residues on the wafer was 50/Wf or more and less than 100/Wf.
C: The total number of organic residues on the wafer was 100/Wf or more and less than 150/Wf.
D: The total number of organic residues on the wafer was 150/Wf or more and less than 200/Wf.
E: The total number of organic residues on the wafer was 200/Wf or more.

### <<Evaluation of Interfacial Corrosion Suppressibility>>

For the polished surface of the treatment target for evaluation obtained in Evaluation of Scratch Suppressibility above, the height difference at the interface between a Cu wiring line (L/S= 1/9) and an insulating film (which is the field surface of the wafer and means an insulating film surface where the Cu wiring line is absent) at chips at the center point, an edge point, and the midpoint between the center point and the edge point of the wafer was determined using an atomic force microscope (AFM, AFM550M manufactured by Hitachi High-Technologies Corporation). From the amount of reduction in height of the Cu wiring line in the vertical direction based on the height of the SiOC surface of the wafer, interfacial corrosion suppressibility was evaluated according to the following evaluation criteria. Smaller amounts of reduction in height of the Cu wiring line indicate that the corrosion of Cu at the interface is more suppressed, which is more preferred. The interfacial corrosion suppressibility is preferably D or higher.

### (Evaluation Criteria)

A: The amount of reduction in height of the Cu wiring line at the interface was 10 angstrom or less.

B: The amount of reduction in height of the Cu wiring line at the interface was more than 10 angstrom and 15 angstrom or less.

C: The amount of reduction in height of the Cu wiring line at the interface was more than 15 angstrom and 20 angstrom or less.

D: The amount of reduction in height of the Cu wiring line at the interface was more than 20 angstrom and 25 angstrom or less.

E: The amount of reduction in height of the Cu wiring line at the interface was more than 25 angstrom.

### {Results}

The following Tables show the composition of polishing liquids, the composition of concentrates of washing liquids, the dilution factor of washing liquids, and the evaluation results of Examples and Comparative Examples.

In Tables, the “Content” column shows the content (unit: mass %) of each component relative to the total mass of a polishing liquid or the content (unit: mass %) of each component relative to the total mass of a concentrate of a washing liquid. The column labeled “f) Alcohol” shows the oil content expressed in units of mass ppm.

In Tables, the columns of “pH” of polishing liquids and “pH of concentrate” and “pH after dilution” of washing liquids each show the pH of the liquid in each form measured at 25 °C with the above pH meter.

In Tables, the “(b)/(c)” column shows the mass ratio of the content of a nonionic surfactant (b) to the content of a specific azole compound (c).

In Tables, the “(b)/(d)” column shows the ratio ((b)/(d)) of the content (b) of a nonionic surfactant relative to the total mass of a polishing liquid to the content (d) of an amine compound relative to the total mass of a washing liquid.

In Tables, the “(c)/(d)” column shows the ratio ((c)/(d)) of the content (c) of a specific azole compound relative to the total mass of a polishing liquid to the content (d) of an amine compound relative to the total mass of a washing liquid.

In the “(b)/(d)” column and the “(c)/(d)” column, the content of the amine compound (d) is a content relative to the total mass of a diluted washing liquid used in the evaluations.

In Tables, the “dilution factor (fold)” column shows a dilution factor (volume ratio) at the time when a concentrate having a composition shown in Table is used for tests. For example, when 200 is given in the “dilution factor (fold)” column, it means that a liquid obtained by diluting, 200-fold by volume, a concentrate having a composition shown in Table with pure water as a diluent is used for the above evaluations.

Table 2 is a continuation of Table 1, and Table 3 is a continuation of Table 2. Table 5 is a continuation of Table 4, and Table 6 is a continuation of Table 5. For example, the kit of Example 1 includes a polishing liquid including PL-1, S-1, BTA, and hydrogen peroxide and having a pH of 8.5 and a washing liquid including DMAMP and PMDTA and having a pH after concentration of 11.0 and a pH after dilution of 10.8.

TABLE 1

| | Polishing liquid | | | | | | | | | | | |
|---|---|---|---|---|---|---|---|---|---|---|---|---|
| | a) Abrasive | | b) Nonionic | | | | | | | | | |
| | grain | | surfactant | | c) Specific azole compound | | | | e) Organic acid | | f) Alcohol | |
| | Type | Content | Type | Content | Type | Content | Type | Content | Type | Content | Type | Content |
| Example 1 | PL-1 | 2 | S-1 | 0.05 | BTA | 0.05 | | | | | | |
| Example 2 | PL-1 | 2 | S-1 | 0.05 | BTA | 0.05 | | | | | | |
| Example 3 | PL-1 | 2 | S-1 | 0.05 | BTA | 0.05 | | | | | | |
| Example 4 | PL-1 | 2 | S-1 | 0.05 | BTA | 0.05 | | | | | | |
| Example 5 | PL-1 | 2 | S-1 | 0.05 | BTA | 0.05 | | | | | | |
| Example 6 | PL-3 | 2 | S-1 | 0.05 | BTA | 0.05 | | | | | | |
| Example 7 | PL-5 | 2 | S-1 | 0.05 | BTA | 0.05 | | | | | | |
| Example 8 | PL-10 | 2 | S-1 | 0.05 | BTA | 0.05 | | | | | | |
| Example 9 | PL-1 | 2 | S-1 | 0.005 | BTA | 1 | | | | | | |
| Example 10 | PL-1 | 2 | S-1 | 0.005 | BTA | 0.5 | | | | | | |
| Example 11 | PL-1 | 2 | S-1 | 0.05 | BTA | 0.05 | | | | | | |
| Example 12 | PL-1 | 2 | S-1 | 0.5 | BTA | 0.05 | | | | | | |
| Example 13 | PL-1 | 2 | S-1 | 0.5 | BTA | 0.01 | | | | | | |
| Example 14 | PL-1 | 2 | S-1 | 1 | BTA | 0.01 | | | | | | |
| Example 15 | PL-1 | 2 | S-1 | 1.5 | BTA | 0.01 | | | | | | |
| Example 16 | PL-1 | 2 | S-1 | 0.05 | BTA | 0.05 | | | citric acid | 0.2 | | |
| Example 17 | PL-1 | 2 | S-1 | 0.05 | BTA | 0.05 | | | malonic | 0.2 | | |
| | | | | | | | | | acid | | | |
| Example 18 | PL-1 | 2 | S-1 | 0.05 | BTA | 0.05 | | | malonic | 0.2 | | |
| | | | | | | | | | acid | | | |
| | | | | | | | | | citric acid | 0.05 | | |
| Example 19 | PL-1 | 2 | S-1 | 0.05 | BTA | 0.05 | | | EDTPO | 0.05 | | |
| Example 20 | PL-1 | 2 | S-1 | 0.05 | BTA | 0.05 | | | | | methanol | 0.1 |
| Example 21 | PL-1 | 2 | S-1 | 0.05 | BTA | 0.05 | | | | | methanol | 1 |
| Example 22 | PL-1 | 2 | S-1 | 0.05 | BTA | 0.05 | | | | | methanol | 10 |
| Example 23 | PL-1 | 2 | S-1 | 0.05 | BTA | 0.05 | | | | | methanol | 150 |
| Example 24 | PL-1 | 2 | S-1 | 0.05 | BTA | 0.05 | | | | | methanol | 1000 |
| Example 25 | PL-1 | 2 | S-1 | 0.05 | BTA | 0.05 | | | | | methanol | 2500 |
| Example 26 | PL-1 | 2 | S-1 | 0.05 | BTA | 0.05 | | | | | ethanol | 150 |
| Example 27 | PL-1 | 2 | S-1 | 0.05 | BTA | 0.05 | | | | | isopropanol | 150 |
| Example 28 | PL-1 | 2 | S-1 | 0.05 | BTA | 0.05 | | | | | 1-propanol | 150 |
| Example 29 | PL-1 | 2 | S-1 | 0.05 | BTA | 0.05 | | | citric acid | 0.2 | ethanol | 150 |
| Example 30 | PL-1 | 2 | S-1 | 0.05 | CBTA | 0.05 | MBTA | 0.05 | citric acid | 0.2 | ethanol | 150 |
| Example 31 | PL-1 | 2 | S-1 | 0.05 | CBTA | 0.05 | | | citric acid | 0.2 | ethanol | 150 |
| Example 32 | PL-1 | 2 | S-1 | 0.05 | BBTA | 0.01 | | | citric acid | 0.2 | ethanol | 150 |
| Example 33 | PL-1 | 2 | S-1 | 0.05 | BTA | 0.04 | MBTA | 0.01 | citric acid | 0.2 | ethanol | 150 |
| Example 34 | PL-1 | 2 | S-1 | 0.05 | MBTA | 0.05 | compound | 0.0002 | citric acid | 0.2 | ethanol | 150 |
| | | | | | | | A | | | | | |
| Example 35 | PL-1 | 2 | S-1 | 0.05 | MBTA | 0.05 | compound | 0.0002 | citric acid | 0.2 | ethanol | 150 |
| | | | | | | | B | | | | | |
| Example 36 | PL-1 | 2 | S-1 | 0.05 | MBTA | 0.05 | compound | 0.0002 | citric acid | 0.2 | ethanol | 150 |
| | | | | | | | C | | | | | |
| Example 37 | PL-1 | 2 | S-1 | 0.05 | BTA | 0.05 | compound | 0.005 | citric acid | 0.2 | ethanol | 150 |
| | | | | | | | A | | | | | |
| Example 38 | PL-1 | 2 | S-1 | 0.05 | BTA | 0.05 | compound | 0.005 | citric acid | 0.2 | ethanol | 150 |
| | | | | | | | A | | | | | |
| Example 39 | PL-1 | 2 | S-1 | 0.05 | BTA | 0.05 | compound | 0.005 | citric acid | 0.2 | ethanol | 150 |
| | | | | | | | A | | | | | |
| Example 40 | PL-1 | 2 | S-2 | 0.05 | CBTA | 0.05 | | | citric acid | 0.2 | ethanol | 150 |
| Example 41 | PL-1 | 2 | S-3 | 0.05 | CBTA | 0.05 | | | citric acid | 0.2 | ethanol | 150 |
| Example 42 | PL-1 | 2 | S-4 | 0.05 | CBTA | 0.05 | | | citric acid | 0.2 | ethanol | 150 |
| Example 43 | PL-1 | 2 | S-5 | 0.05 | CBTA | 0.05 | | | citric acid | 0.2 | ethanol | 150 |
| Example 44 | PL-1 | 2 | S-6 | 0.05 | CBTA | 0.05 | | | citric acid | 0.2 | ethanol | 150 |
| Example 45 | PL-1 | 2 | S-7 | 0.05 | CBTA | 0.05 | | | citric acid | 0.2 | ethanol | 150 |
| Example 46 | PL-1 | 2 | S-8 | 0.05 | CBTA | 0.05 | | | citric acid | 0.2 | ethanol | 150 |

TABLE 2

| | Polishing liquid | | | | Washing liquid | | | | | | | |
|---|---|---|---|---|---|---|---|---|---|---|---|---|
| | | | Oxidizing agent | | d) Amine compound | | | | e) Anticorrosive | | Others | |
| | (b)/(c) | pH | Type | Content | Type | Content | Type | Content | Type | Content | Type | Content |
| Example 1 | 1 | 8.5 | hydrogen peroxide | 2 | DMAMP | 3.5 | PMDTA | 1.5 | | | | |
| Example 2 | 1 | 9 | hydrogen peroxide | 2 | DMAMP | 3.5 | PMDTA | 1.5 | | | | |
| Example 3 | 1 | 10 | hydrogen peroxide | 2 | DMAMP | 3.5 | PMDTA | 1.5 | | | | |
| Example 4 | 1 | 11 | hydrogen peroxide | 2 | DMAMP | 3.5 | PMDTA | 1.5 | | | | |
| Example 5 | 1 | 12 | hydrogen peroxide | 2 | DMAMP | 3.5 | PMDTA | 1.5 | | | | |
| Example 6 | 1 | 10 | hydrogen peroxide | 2 | DMAMP | 3.5 | PMDTA | 1.5 | | | | |
| Example 7 | 1 | 10 | hydrogen peroxide | 2 | DMAMP | 3.5 | PMDTA | 1.5 | | | | |
| Example 8 | 1 | 10 | hydrogen peroxide | 2 | DMAMP | 3.5 | PMDTA | 1.5 | | | | |
| Example 9 | 0.01 | 10 | hydrogen peroxide | 2 | DMAMP | 3.5 | PMDTA | 1.5 | | | | |
| Example 10 | 0.01 | 10 | hydrogen peroxide | 2 | DMAMP | 3.5 | PMDTA | 1.5 | | | | |
| Example 11 | 1 | 10 | hydrogen peroxide | 2 | DMAMP | 3.5 | PMDTA | 1.5 | | | | |
| Example 12 | 10 | 10 | hydrogen peroxide | 2 | DMAMP | 3.5 | PMDTA | 1.5 | | | | |
| Example 13 | 50 | 10 | hydrogen peroxide | 2 | DMAMP | 3.5 | PMDTA | 1.5 | | | | |
| Example 14 | 100 | 10 | hydrogen peroxide | 2 | DMAMP | 3.5 | PMDTA | 1.5 | | | | |
| Example 15 | 150 | 10 | hydrogen peroxide | 2 | DMAMP | 3.5 | PMDTA | 1.5 | | | | |
| Example 16 | 1 | 10 | hydrogen peroxide | 2 | DMAMP | 3.5 | PMDTA | 1.5 | | | | |
| Example 17 | 1 | 10 | hydrogen peroxide | 2 | DMAMP | 3.5 | PMDTA | 1.5 | | | | |
| Example 18 | 1 | 10 | hydrogen peroxide | 2 | DMAMP | 3.5 | PMDTA | 1.5 | | | | |
| Example 19 | 1 | 10 | hydrogen peroxide | 2 | DMAMP | 3.5 | PMDTA | 1.5 | | | | |
| Example 20 | 1 | 10 | hydrogen peroxide | 2 | DMAMP | 3.5 | PMDTA | 1.5 | | | | |
| Example 21 | 1 | 10 | hydrogen peroxide | 2 | DMAMP | 3.5 | PMDTA | 1.5 | | | | |
| Example 22 | 1 | 10 | hydrogen peroxide | 2 | DMAMP | 3.5 | PMDTA | 1.5 | | | | |
| Example 23 | 1 | 10 | hydrogen peroxide | 2 | DMAMP | 3.5 | PMDTA | 1.5 | | | | |
| Example 24 | | 10 | hydrogen peroxide | 2 | DMAMP | 3.5 | PMDTA | 1.5 | | | | |
| Example 25 | 1 | 10 | hydrogen peroxide | 2 | DMAMP | 3.5 | PMDTA | 1.5 | | | | |
| Example 26 | 1 | 10 | hydrogen peroxide | 2 | DMAMP | 3.5 | PMDTA | 1.5 | | | | |
| Example 27 | 1 | 10 | hydrogen peroxide | 2 | DMAMP | 3.5 | PMDTA | 1.5 | | | | |
| Example 28 | 1 | 10 | hydrogen peroxide | 2 | DMAMP | 3.5 | PMDTA | 1.5 | | | | |
| Example 29 | 1 | 10 | hydrogen peroxide | 2 | DMAMP | 3.5 | PMDTA | 1.5 | | | | |
| Example 30 | 0.5 | 10 | hydrogen peroxide | 2 | DMAMP | 3.5 | PMDTA | 1.5 | | | | |
| Example 31 | 1 | 10 | hydrogen peroxide | 2 | DMAMP | 3.5 | PMDTA | 1.5 | | | | |
| Example 32 | 5 | 10 | hydrogen peroxide | 2 | DMAMP | 3.5 | PMDTA | 1.5 | | | | |
| Example 33 | 1 | 10 | hydrogen peroxide | 2 | DMAMP | 3.5 | PMDTA | 1.5 | | | | |
| Example 34 | 1 | 10 | hydrogen peroxide | 2 | DMAMP | 3.5 | PMDTA | 1.5 | | | | |
| Example 35 | 1 | 10 | hydrogen peroxide | 2 | DMAMP | 3.5 | PMDTA | 1.5 | | | | |
| Example 36 | 1 | 10 | hydrogen peroxide | 2 | DMAMP | 3.5 | PMDTA | 1.5 | | | | |
| Example 37 | 0.91 | 10 | hydrogen peroxide | 2 | DMAMP | 4 | PMDTA | 2 | | | | |
| Example 38 | 0.91 | 10 | hydrogen peroxide | 2 | DMAMP | 5.5 | PMDTA | 2.5 | | | | |
| Example 39 | 0.91 | 10 | hydrogen peroxide | 2 | DMAMP | 3.5 | PMDTA | 1.5 | | | | |
| Example 40 | 1 | 10 | hydrogen peroxide | 2 | DMAMP | 3.5 | PMDTA | 1.5 | | | | |
| Example 41 | 1 | 10 | hydrogen peroxide | 2 | DMAMP | 3.5 | PMDTA | 1.5 | | | | |
| Example 42 | 1 | 10 | hydrogen peroxide | 2 | DMAMP | 3.5 | PMDTA | 1.5 | | | | |
| Example 43 | 1 | 10 | hydrogen peroxide | 2 | DMAMP | 3.5 | PMDTA | 1.5 | | | | |
| Example 44 | 1 | 10 | hydrogen peroxide | 2 | DMAMP | 3.5 | PMDTA | 1.5 | | | | |
| Example 45 | 1 | 10 | hydrogen peroxide | 2 | DMAMP | 3.5 | PMDTA | 1.5 | | | | |
| Example 46 | 1 | 10 | hydrogen peroxide | 2 | DMAMP | 3.5 | PMDTA | 1.5 | | | | |

TABLE 3

| | Washing liquid | | | | | | | |
|---|---|---|---|---|---|---|---|---|
| | | Dilution | | | | | | |
| | | factor | pH | | | | Organic | Interfacial |
| | pH | (volume | (after | | | Scratch | residue | corrosion |
| | (concentrate) | ratio) | dilution) | (b)/(d) | (c)/(d) | suppressibility | removability | suppressibility |
| Example 1 | 11 | 50 | 10.8 | 0.5 | 0.5 | C | B | C |
| Example 2 | 11 | 50 | 10.8 | 0.5 | 0.5 | B | B | C |
| Example 3 | 11 | 50 | 10.8 | 0.5 | 0.5 | B | B | C |
| Example 4 | 11 | 50 | 10.8 | 0.5 | 0.5 | B | B | C |
| Example 5 | 11 | 50 | 10.8 | 0.5 | 0.5 | B | C | C |
| Example 6 | 11 | 50 | 10.8 | 0.5 | 0.5 | B | B | C |
| Example 7 | 11 | 50 | 10.8 | 0.5 | 0.5 | B | B | C |
| Example 8 | 11 | 50 | 10.8 | 0.5 | 0.5 | C | B | C |
| Example 9 | 11 | 50 | 10.8 | 0.05 | 10 | B | C | C |
| Example 10 | 11 | 50 | 10.8 | 0.05 | 5 | B | B | C |
| Example 11 | 11 | 50 | 10.8 | 0.5 | 0.5 | B | B | C |
| Example 12 | 11 | 50 | 10.8 | 5 | 0.5 | B | B | C |
| Example 13 | 11 | 50 | 10.8 | 5 | 0.1 | B | B | C |
| Example 14 | 11 | 50 | 10.8 | 10 | 0.1 | B | B | C |
| Example 15 | 11 | 50 | 10.8 | 15 | 0.1 | C | B | C |
| Example 16 | 11 | 50 | 10.8 | 0.5 | 0.5 | A | B | C |
| Example 17 | 11 | 50 | 10.8 | 0.5 | 0.5 | A | B | C |
| Example 18 | 11 | 50 | 10.8 | 0.5 | 0.5 | A | B | C |
| Example 19 | 11 | 50 | 10.8 | 0.5 | 0.5 | B | A | C |
| Example 20 | 11 | 50 | 10.8 | 0.5 | 0.5 | B | A | C |
| Example 21 | 11 | 50 | 10.8 | 0.5 | 0.5 | B | A | C |
| Example 22 | 11 | 50 | 10.8 | 0.5 | 0.5 | B | A | C |
| Example 23 | 11 | 50 | 10.8 | 0.5 | 0.5 | B | A | C |
| Example 24 | 11 | 50 | 10.8 | 0.5 | 0.5 | B | A | C |
| Example 25 | 11 | 50 | 10.8 | 0.5 | 0.5 | B | A | D |
| Example 26 | 11 | 50 | 10.8 | 0.5 | 0.5 | B | A | C |
| Example 27 | 11 | 50 | 10.8 | 0.5 | 0.5 | B | A | C |
| Example 28 | 11 | 50 | 10.8 | 0.5 | 0.5 | B | A | C |
| Example 29 | 11 | 50 | 10.8 | 0.5 | 0.5 | A | A | C |
| Example 30 | 11 | 50 | 10.8 | 0.5 | 1 | A | A | C |
| Example 31 | 11 | 50 | 10.8 | 0.5 | 0.5 | A | A | C |
| Example 32 | 11 | 50 | 10.8 | 0.5 | 0.1 | A | A | C |
| Example 33 | 11 | 50 | 10.8 | 0.5 | 0.5 | A | A | C |
| Example 34 | 11 | 50 | 10.8 | 0.5 | 0.502 | A | A | B |
| Example 35 | 11 | 50 | 10.8 | 0.5 | 0.502 | A | A | B |
| Example 36 | 11 | 50 | 10.8 | 0.5 | 0.502 | A | A | B |
| Example 37 | 11 | 50 | 10.8 | 0.417 | 0.458 | A | A | B |
| Example 38 | 11 | 50 | 10.8 | 0.313 | 0.344 | A | A | B |
| Example 39 | 11 | 50 | 10.8 | 0.5 | 0.55 | A | A | B |
| Example 40 | 11 | 50 | 10.8 | 0.5 | 0.5 | A | A | C |
| Example 41 | 11 | 50 | 10.8 | 0.5 | 0.5 | B | A | C |
| Example 42 | 11 | 50 | 10.8 | 0.5 | 0.5 | B | A | C |
| Example 43 | 11 | 50 | 10.8 | 0.5 | 0.5 | A | A | C |
| Example 44 | 11 | 50 | 10.8 | 0.5 | 0.5 | A | A | C |
| Example 45 | 11 | 50 | 10.8 | 0.5 | 0.5 | B | A | C |
| Example 46 | 11 | 50 | 10.8 | 0.5 | 0.5 | B | A | C |

TABLE 4

| | Polishing liquid | | | | | | | | | | | |
|---|---|---|---|---|---|---|---|---|---|---|---|---|
| | a) Abrasive | | b) Nonionic | | | | | | | | | |
| | grain | | surfactant | | c) Specific azole compound | | | | e) Organic acid | | f) Alcohol | |
| | Type | Content | Type | Content | Type | Content | Type | Content | Type | Content | Type | Content |
| Example 47 | PL-1 | 2 | S-1 | 0.05 | CBTA | 0.05 | compound A | 0.0002 | citric acid | 0.2 | ethanol | 150 |
| Example 48 | PL-1 | 2 | S-1 | 0.05 | CBTA | 0.05 | compound A | 0.0002 | citric acid | 0.2 | ethanol | 150 |
| Example 49 | PL-1 | 2 | S-1 | 0.05 | CBTA | 0.05 | compound A | 0.0002 | citric acid | 0.2 | ethanol | 150 |
| Example 50 | PL-1 | 2 | S-1 | 0.05 | CBTA | 0.05 | compound A | 0.0002 | citric acid | 0.2 | ethanol | 150 |
| Example 51 | PL-1 | 2 | 5-1 | 0.05 | CBTA | 0.05 | compound A | 0.0002 | citric acid | 0.2 | ethanol | 150 |
| Example 52 | PL-1 | 2 | S-1 | 0.05 | CBTA | 0.05 | compound A | 0.0002 | citric acid | 0.2 | ethanol | 150 |
| Example 53 | PL-1 | 2 | S-1 | 0.05 | CBTA | 0.05 | compound A | 0.0002 | citric acid | 0.2 | ethanol | 150 |
| Example 54 | PL-1 | 2 | S-1 | 0.05 | CBTA | 0.05 | compound A | 0.0002 | citric acid | 0.2 | ethanol | 150 |
| Example 55 | PL-1 | 2 | S-1 | 0.05 | CBTA | 0.05 | compound A | 0.0002 | citric acid | 0.2 | ethanol | 150 |
| Example 56 | PL-1 | 2 | 5-1 | 0.05 | CBTA | 0.05 | compound A | 0.0002 | citric acid | 0.2 | ethanol | 150 |
| Example 57 | PL-1 | 2 | S-1 | 0.05 | CBTA | 0.05 | compound A | 0.0002 | citric acid | 0.2 | ethanol | 150 |
| Example 58 | PL-1 | 2 | S-1 | 0.005 | CBTA | 0.05 | compound A | 0.0002 | citric acid | 0.2 | ethanol | 150 |
| Example 59 | PL-1 | 2 | S-1 | 0.01 | CBTA | 0.05 | compound A | 0.0002 | citric acid | 0.2 | ethanol | 150 |
| Example 60 | PL-1 | 2 | S-1 | 0.05 | CBTA | 0.05 | compound A | 0.0002 | citric acid | 0.2 | ethanol | 150 |
| Example 61 | PL-1 | 2 | S-1 | 0.5 | CBTA | 0.05 | compound A | 0.0002 | citric acid | 0.2 | ethanol | 150 |
| Example 62 | PL-1 | 2 | S-1 | 0.5 | CBTA | 0.05 | compound A | 0.0002 | citric acid | 0.2 | ethanol | 150 |
| Example 63 | PL-1 | 2 | S-1 | 0.05 | CBTA | 0.0003 | compound A | 0.0002 | citric acid | 0.2 | ethanol | 150 |
| Example 64 | PL-1 | 2 | S-1 | 0.05 | CBTA | 0.0005 | compound A | 0.0002 | citric acid | 0.2 | ethanol | 150 |
| Example 65 | PL-1 | 2 | S-1 | 0.05 | CBTA | 0.01 | compound A | 0.0002 | citric acid | 0.2 | ethanol | 150 |
| Example 66 | PL-1 | 2 | S-1 | 0.05 | CBTA | 0.05 | compound A | 0.0002 | citric acid | 0.2 | ethanol | 150 |
| Example 67 | PL-1 | 2 | S-1 | 0.05 | CBTA | 0.05 | compound A | 0.0002 | citric acid | 0.2 | ethanol | 150 |
| Comparative | PL-1 | 5 | S-1 | 0.5 | | | | | glycine | 1 | ethanol | 150 |
| Example 1 | | | | | | | | | | | | |
| Comparative | PL-1 | 2 | S-1 | 0.05 | CBTA | 0.05 | compound A | 0.0002 | citric acid | 0.2 | ethanol | 150 |
| Example 2 | | | | | | | | | | | | |
| Comparative | PL-1 | 5 | S-1 | 0.5 | | | | | glycine | 1 | ethanol | 150 |
| Example 3 | | | | | | | | | | | | |

TABLE 5

| | Polishing liquid | | | | Washing liquid | | | | | | | |
|---|---|---|---|---|---|---|---|---|---|---|---|---|
| | | | Oxidizing agent | | d) Amine compound | | | | e) Anticorrosive | | Others | |
| | (b)/(c) | pH | Type | Content | Type | Content | Type | Content | Type | Content | Type | Content |
| Example 47 | 1 | 10 | hydrogen | 2 | DMAMP | 3.5 | PMDTA | 1.5 | | | | |
| | | | peroxide | | | | | | | | | |
| Example 48 | 1 | 10 | hydrogen | 2 | DMAMP | 3.5 | PMDTA | 1.5 | | | | |
| | | | peroxide | | | | | | | | | |
| Example 49 | 1 | 10 | hydrogen | 2 | DMAMP | 3.5 | PMDTA | 1.5 | | | | |
| | | | peroxide | | | | | | | | | |
| Example 50 | 1 | 10 | hydrogen | 2 | ETMAH | 3.5 | PMDTA | 1.5 | | | | |
| | | | peroxide | | | | | | | | | |
| Example 51 | 1 | 10 | hydrogen | 2 | DMAMP | 3.5 | AMP | 1.2 | adenine | 0.2 | | |
| | | | peroxide | | | | | | | | | |
| Example 52 | 1 | 10 | hydrogen | 2 | THEMAH | 5.5 | MDEA | 1.5 | xanthine | 0.2 | succinic | 0.12 |
| | | | peroxide | | | | | | | | acid | |
| Example 53 | 1 | 10 | hydrogen | 2 | THEMAH | 5.5 | MDEA | 1.5 | xanthine | 0.2 | succinic | 0.12 |
| | | | peroxide | | | | | | | | acid | |
| Example 54 | 1 | 10 | hydrogen | 2 | THEMAH | 5.5 | MDEA | 1.5 | xanthine | 0.2 | succinic | 0.12 |
| | | | peroxide | | | | | | | | acid | |
| Example 55 | 1 | 10 | hydrogen | 2 | THEMAH | 5.5 | MDEA | 1.5 | xanthine | 0.2 | succinic | 0.12 |
| | | | peroxide | | | | | | | | acid | |
| Example 56 | 1 | 10 | hydrogen | 2 | THEMAH | 5.5 | MDEA | 1.5 | xanthine | 0.2 | succinic | 0.12 |
| | | | peroxide | | | | | | | | acid | |
| Example 57 | 1 | 10 | hydrogen | 2 | DMAMP | 3.5 | PMDTA | 1.5 | adenine | 0.2 | | |
| | | | peroxide | | | | | | | | | |
| Example 58 | 0.1 | 10 | hydrogen | 2 | THEMAH | 5.5 | MDEA | 1.5 | xanthine | 0.2 | | |
| | | | peroxide | | | | | | | | | |
| Example 59 | 0.2 | 10 | hydrogen | 2 | THEMAH | 5.5 | MDEA | 1.5 | xanthine | 0.2 | | |
| | | | peroxide | | | | | | | | | |
| Example 60 | 1 | 10 | hydrogen | 2 | THEMAH | 5.5 | MDEA | 1.5 | xanthine | 0.2 | | |
| | | | peroxide | | | | | | | | | |
| Example 61 | 9.96 | 10 | hydrogen | 2 | THEMAH | 4.7 | MDEA | 0.3 | xanthine | 0.2 | | |
| | | | peroxide | | | | | | | | | |
| Example 62 | 9.96 | 10 | hydrogen | 2 | THEMAH | 2.5 | MDEA | 0.1 | xanthine | 0.2 | | |
| | | | peroxide | | | | | | | | | |
| Example 63 | 100 | 10 | hydrogen | 2 | THEMAH | 5.5 | MDEA | 1.5 | xanthine | 0.2 | | |
| | | | peroxide | | | | | | | | | |
| Example 64 | 71.43 | 10 | hydrogen | 2 | THEMAH | 5.5 | MDEA | 1.5 | xanthine | 0.2 | | |
| | | | peroxide | | | | | | | | | |
| Example 65 | 4.9 | 10 | hydrogen | 2 | THEMAH | 5.5 | MDEA | 1.5 | xanthine | 0.2 | | |
| | | | peroxide | | | | | | | | | |
| Example 66 | 1 | 10 | hydrogen | 2 | THEMAH | 4.7 | MDEA | 0.3 | xanthine | 0.2 | | |
| | | | peroxide | | | | | | | | | |
| Example 67 | 1 | 10 | hydrogen | 2 | THEMAH | 2.5 | MDEA | 0.1 | xanthine | 0.2 | | |
| | | | peroxide | | | | | | | | | |
| Comparative | | 7 | hydrogen | 2 | | | | | xanthine | 0.2 | | |
| Example 1 | | | peroxide | | | | | | | | | |
| Comparative | 1 | 10 | hydrogen | 2 | | | | | xanthine | 0.2 | | |
| Example 2 | | | peroxide | | | | | | | | | |
| Comparative | | 7 | hydrogen | 2 | THEMAH | 2.5 | PMDTA | 0.1 | xanthine | 0.2 | | |
| Example 3 | | | peroxide | | | | | | | | | |

TABLE 6

| | Washing liquid | | | | | | | |
|---|---|---|---|---|---|---|---|---|
| | | Dilution | | | | | | |
| | | factor | pH | | | | | Interfacial |
| | pH | (volume | (after | | | Scratch | Organic residue | corrosion |
| | (concentrate) | ratio) | dilution) | (b)/(d) | (c)/(d) | suppressibility | removability | suppressibility |
| Example 47 | 8 | 50 | 7.5 | 0.5 | 0.502 | A | B | B |
| Example 48 | 10 | 50 | 9.5 | 0.5 | 0.502 | A | A | B |
| Example 49 | 12 | 50 | 10.8 | 0.5 | 0.502 | A | A | B |
| Example 50 | 14 | 50 | 11.2 | 0.5 | 0.502 | A | A | B |
| Example 51 | 11 | 50 | 10.8 | 0.532 | 0.534 | A | A | A |
| Example 52 | 13 | 50 | 10.8 | 0.357 | 0.359 | A | A | A |
| Example 53 | 13 | 10 | 11.2 | 0.071 | 0.072 | A | A | B |
| Example 54 | 13 | 100 | 11.2 | 0.714 | 0.717 | A | A | A |
| Example 55 | 13 | 200 | 11.2 | 1.429 | 1.434 | A | B | A |
| Example 56 | 13 | 300 | 11.2 | 2.143 | 2.151 | A | B | B |
| Example 57 | 11 | 50 | 10.8 | 0.5 | 0.502 | A | A | A |
| Example 58 | 13 | 50 | 11.2 | 0.036 | 0.359 | A | B | A |
| Example 59 | 13 | 50 | 11.2 | 0.071 | 0.359 | A | A | A |
| Example 60 | 13 | 50 | 11.2 | 0.357 | 0.359 | A | A | A |
| Example 61 | 13 | 50 | 11.2 | 5 | 0.502 | A | A | A |
| Example 62 | 13 | 50 | 11.2 | 9.615 | 0.965 | A | B | A |
| Example 63 | 13 | 50 | 11.2 | 0.357 | 0.0036 | A | A | B |
| Example 64 | 13 | 50 | 11.2 | 0.357 | 0.005 | A | A | A |
| Example 65 | 13 | 50 | 11.2 | 0.357 | 0.073 | A | A | A |
| Example 66 | 13 | 50 | 11.2 | 0.5 | 0.502 | A | A | A |
| Example 67 | 13 | 50 | 11.2 | 0.962 | 0.965 | A | B | A |
| Comparative | 9 | 50 | 8.4 | | | E | E | E |
| Example 1 | | | | | | | | |
| Comparative | 9 | 50 | 8.4 | | | A | E | A |
| Example 2 | | | | | | | | |
| Comparative | 13 | 50 | 11.2 | 0.004 | | E | A | E |
| Example 3 | | | | | | | | |

The results in the above Tables have demonstrated that when used for a treatment in which a treatment target is subjected to chemical mechanical polishing and the treatment target subjected to chemical mechanical polishing is further washed, the kits of Comparative Example do not produce the desired effects in at least one of scratch suppressibility or organic residue removability, whereas the kits of the present invention have high scratch suppressibility and high organic residue removability. It has also been demonstrated that the kits of the present invention also have high interfacial corrosion suppressibility.

Comparison of Examples 1 to 5 has demonstrated that when the pH of the polishing liquid is 8.8 or more, scratch suppressibility is higher, and when it is 11.5 or less, the organic residue removability is higher.

Comparison of Examples 3 and 6 to 8 has demonstrated that when the average particle diameter of the abrasive grain is 5 to 100 nm, the scratch suppressibility is higher.

Comparison of Examples 9 to 15 has demonstrated that when the mass ratio of the content of the nonionic surfactant to the content of the specific azole compound is 0.01 or more, the organic residue removability is higher, and when it is 100.00 or less, the scratch suppressibility is higher.

Comparison of Examples 3 and 16 to 19 has demonstrated that when the polishing liquid includes an organic acid, the scratch suppressibility is higher.

Comparison of Examples 3 and 20 to 28 has demonstrated that when the polishing liquid includes an alcohol, the organic residue removability is higher, and when the content of the alcohol is 0.1 to 1000 mass ppm relative to the total mass of the polishing liquid, the interfacial corrosion suppressibility is higher.

Comparison of Examples 29 to 36 and 39 has demonstrated that when the polishing liquid includes two or more specific azole compounds and at least one of the specific azole compounds is a compound represented by formula (I) or a compound represented by formula (II), the interfacial corrosion suppressibility is higher.

Comparison of Examples 49 to 46 has demonstrated that when the nonionic surfactant is an alkyl alkoxylate, the scratch suppressibility is higher.

Comparison of Examples 47 to 50 has demonstrated that when the pH of the washing liquid is 9.0 to 14.0, the organic residue removability is higher.

Comparison of Example 48 with Example 51 has demonstrated that when the washing liquid includes an anticorrosive, the interfacial corrosion suppressibility is higher.

Comparison of Example 48 with Examples 53 to 56 has demonstrated that the effects of the present invention are produced well even if the dilution factors of the washing liquids are different.

Comparison of Example 48 with Example 53 to 56 has demonstrated that when the content of the amine compound is 0.03 mass % or more relative to the total mass of the washing liquid, the interfacial corrosion suppressibility is higher, and when it is 0.06 mass % or more, the organic residue removability is higher.

Comparison of Examples 37 to 39 and 52 to 56 has demonstrated that when the content of the amine compound is 0.6 mass % or less relative to the total mass of the washing liquid, the interfacial corrosion suppressibility is higher.

Comparison of Examples 58 to 62 has demonstrated that when the ratio of the content of the nonionic surfactant relative to the total mass of the polishing liquid to the content of the amine compound relative to the total mass of the washing liquid is 0.05 to 8.00, the organic residue removability is higher.

Comparison of Examples 63 to 67 has demonstrated that when the ratio of the content of the specific azole compound relative to the total mass of the polishing liquid to the content of the amine compound relative to the total mass of the washing liquid is 0.005 or more, the interfacial corrosion suppressibility is higher, and when it is 0.90 or less, the organic residue removability is higher.

What is claimed is:

1. A kit for use in subjecting a treatment target to chemical mechanical polishing and further washing the treatment target subjected to chemical mechanical polishing, the kit comprising:
a polishing liquid; and
a washing liquid,
wherein the polishing liquid includes an abrasive grain, a nonionic surfactant, and a specific azole compound selected from the group consisting of benzotriazole and derivatives thereof and has a pH of 7.0 or more, and
the washing liquid includes an amine compound.

2. The kit according to claim 1, wherein the pH of the polishing liquid is 8.8 to 11.5.

3. The kit according to claim 1, wherein the abrasive grain is a colloidal silica having an average particle diameter of 5 to 100 nm.

4. The kit according to claim 1, wherein a mass ratio of a content of the nonionic surfactant to a content of the specific azole compound is 0.01 to 100.00.

5. The kit according to claim 1, wherein at least one of the polishing liquid or the washing liquid further includes an organic acid.

6. The kit according to claim 5, wherein the organic acid includes at least one organic acid selected from the group consisting of polycarboxylic acids and polyphosphonic acids.

7. The kit according to claim 1, wherein the polishing liquid further includes an alcohol.

8. The kit according to claim 7, wherein a content of the alcohol is 0.1 to 1000 mass ppm relative to a total mass of the polishing liquid.

9. The kit according to claim 7, wherein the alcohol is selected from the group consisting of methanol, ethanol, 1-propanol, and isopropanol.

10. The kit according to claim 1, wherein the specific azole compound included in the polishing liquid comprises at least two specific azole compounds.

11. The kit according to claim 10, wherein at least one of the specific azole compounds is a compound represented by formula (I) or a compound represented by formula (II), 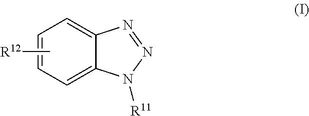
in formula (I), R¹¹ and R¹² each independently represent a hydrogen atom, a hydroxy group, a carboxy group, or an optionally substituted hydrocarbon group, provided that the compound represented by formula (I) does not include any of benzotriazole, 5-methylbenzotriazole, 5-chlorobenzotriazole, and 5-butylbenzotriazole, 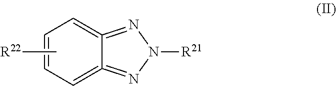
in formula (II), R²¹ and R²² each independently represent a hydrogen atom, a hydroxy group, a carboxy group, or an optionally substituted hydrocarbon group, provided that the compound represented by formula (II) does not include any of benzotriazole, 5-methylbenzotriazole, 5-chlorobenzotriazole, and 5-butylbenzotriazole.

12. The kit according to claim 1, wherein the nonionic surfactant is an alcohol alkoxylate.

13. The kit according to claim 1, wherein the washing liquid has a pH of 9.0 to 14.0.

14. The kit according to claim 1, wherein the washing liquid further includes an anticorrosive.

15. The kit according to claim 14, wherein the anticorrosive includes at least one compound selected from the group consisting of purine and purine derivatives.

16. The kit according to claim 1, wherein a content of the amine compound is 0.06 to 8.0 mass % relative to a total mass of the washing liquid.

17. The kit according to claim 1, wherein a ratio of a content of the nonionic surfactant relative to a total mass of the polishing liquid to a content of the amine compound relative to a total mass of the washing liquid is 0.05 to 8.00.

18. The kit according to claim 1, wherein a ratio of a content of the specific azole compound relative to a total mass of the polishing liquid to a content of the amine compound relative to a total mass of the washing liquid is 0.005 to 0.90.

19. The kit according to claim 1, wherein the amine compound is at least one amine compound selected from the group consisting of secondary amine compounds, tertiary amine compounds, and quaternary ammonium compounds.

20. The kit according to claim 1, wherein the amine compound includes at least one selected from the group consisting of a compound represented by formula (A1) and a compound represented by formula (A2), 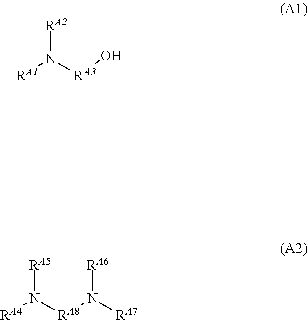
in formula (A1),
R^{A1} and R^{A2} each independently represent a hydrogen atom or an optionally substituted alkyl group having 1 to 3 carbon atoms, provided that at least one of R^{A1} or R^{A2} represents an optionally substituted alkyl group having 1 to 3 carbon atoms,
R^{A3} represents an optionally substituted alkylene group having 1 to 4 carbon atoms, and two of R^{A1} to R^{A3} may be bonded to each other through a single bond or a divalent linking group to form a ring,
in formula (A2),
R^{A4} to R^{A7} each independently represent a hydrogen atom or an optionally substituted alkyl group having 1 to 3 carbon atoms, provided that at least one of R^{A4} to R^{A7} represents an optionally substituted alkyl group,
R^{A8} represents an alkylene group having 1 to 6 carbon atoms that optionally has a hydroxy group and optionally has a linking group represented by —NR^{Ax}— or —O—, where R^{Ax} represents a hydrogen atom or an alkyl group having 1 to 3 carbon atoms, and
two of R^{A4} to R^{A7} may be bonded to each other through a single bond or a divalent linking group to form a ring.

21. The kit according to claim 1, wherein the treatment target includes copper.

22. A method for manufacturing a semiconductor device using the kit according to claim 1, the method comprising:
a step 1 of subjecting a treatment target to chemical mechanical polishing using the polishing liquid; and
a step 2, after the step 1, of washing the treatment target subjected to chemical mechanical polishing using the washing liquid.

23. The method according to claim 22, further comprising:
a step 1a, after step 1 and prior to step 2, of pad washing the treatment target subjected to chemical mechanical polishing using the washing liquid as a composition for pad washing.
